(19) United States
(12) Patent Application Publication
(10) Pub. No.: US 2025/0306061 A1
(43) Pub. Date: Oct. 2, 2025

(54) CURRENT SENSOR AND CURRENT MEASUREMENT DEVICE

(71) Applicant: Asahi Kasei Microdevices Corporation, Tokyo (JP)

(72) Inventor: Masaki TSUJIMOTO, Tokyo (JP)

(21) Appl. No.: 19/088,890

(22) Filed: Mar. 24, 2025

(30) Foreign Application Priority Data
Mar. 26, 2024 (JP) 2024-049423
Mar. 14, 2025 (JP) 2025-040761

(51) Int. Cl. G01R 15/20; G01R 19/00

(52) U.S. Cl. CPC G01R 15/202; G01R 19/0092

(57) ABSTRACT

A current sensor may include: at least one magnetoelectric conversion unit; a current conductor through which a measurement current measured by the magnetoelectric conversion unit flows; and a conductor plate which at least partially overlaps the current conductor in plan view. A main body portion of the current conductor includes a first portion. A thickness of the conductor plate, magnetic permeabilities of the conductor plate and the current conductor, electrical conductivities of the conductor plate and the current conductor, a shortest distance between a magnetic sensing surface and the current conductor, a maximum width of the first portion, a shorter distance of a distance between the conductor plate and the current conductor and a distance between the conductor plate and the magnetic sensing surface of the magnetoelectric conversion unit, and a narrowest width in a portion, which crosses the magnetoelectric conversion unit, of the conductor plate satisfy a condition.

The contents of the following patent application(s) are incorporated herein by reference:
NO. 2024-049423 filed in JP on Mar. 26, 2024
NO. 2025-040761 filed in JP on Mar. 14, 2025.

### BACKGROUND

### 1. Technical Field

The present invention relates to a current sensor and a current measurement device.

### 2. Related Art

Patent Document 1 discloses a current sensor including a primary conductor having an opening, a lead frame having a portion overlapping the opening, and a magnetic sensor. Patent Document 2 discloses a current sensor in which a support member that supports a magnetoelectric conversion element is constituted by a semiconductor substrate or a metal plate. Patent Document 3 discloses that an external current rail is arranged at a position facing a sensor element on a substrate on which a sensor package incorporating the sensor element is mounted. Patent Documents 4 and 5 disclose that a magnetic sensor is at least partially surrounded by a current conductor.

### PRIOR ART DOCUMENTS

### Patent Documents

Patent Document 1: Japanese Patent Application Publication No. 2018-36237
Patent Document 2: Japanese Patent No. 7328430
Patent Document 3: U.S. Pat. No. 9,733,280
Patent Document 4: U.S. Patent Application Publication No. 2022/0091161
Patent Document 5: U.S. Patent Application Publication No. 2015/0160272

### BRIEF DESCRIPTION OF THE DRAWINGS

FIG. 1A is a schematic plan view of a current sensor 10 according to the present embodiment as viewed from a ceiling surface side (Z axis direction).

FIG. 1B is a cross-sectional view taken along line A-A of the current sensor 10 illustrated in FIG. 1A.

FIG. 2 is a diagram illustrating an example of frequency dependence showing a relationship between a sensitivity variation of a magnetoelectric conversion element and a frequency of a current flowing through a current conductor.

FIG. 3 is a diagram illustrating an example of a relationship between the sensitivity variation of the magnetoelectric conversion element in which three side surfaces are surrounded by the current conductor and a distance between the current conductor and a conductor plate.

FIG. 4 is a diagram illustrating an example of a relationship between the sensitivity variation of one magnetoelectric conversion element when current sensing is performed based on a difference from outputs of two magnetoelectric conversion elements, and the distance between the current conductor and the conductor plate.

FIG. 5 is a diagram illustrating an example of a graph showing a relationship between the sensitivity variation and the frequency, the relationship being derived by Expression 3.

FIG. 6 is a diagram illustrating an example of a simulation result when a vertical axis represents the sensitivity variation of the magnetoelectric conversion element for the frequency of 10 MHz and a horizontal axis represents a conductor width.

FIG. 7 is a diagram illustrating a relationship between the sensitivity variation of the magnetoelectric conversion element and the distance between the current conductor and the conductor plate.

FIG. 8A is a diagram for explaining a distance z_{b} when a magnetic sensing surface of the magnetoelectric conversion element is at a position lower than a surface of the current conductor facing a signal processing IC.

FIG. 8B is a diagram for explaining the distance z_{b} when the magnetic sensing surface of the magnetoelectric conversion element is at a position higher than the surface of the current conductor facing the signal processing IC 100.

FIG. 9 is a diagram illustrating a relationship between the sensitivity variation of the magnetoelectric conversion element and the distance z_{b}.

FIG. 10 is a diagram for explaining definitions of parameters related to a coil and a conductor.

FIG. 11 is a diagram illustrating the relationship between the sensitivity variation rate due to eddy currents and an electrical conductivity of the conductor plate.

FIG. 12 is a graph showing a relationship between a normalized sensitivity variation rate according to a positional relationship of the conductor plate, the current conductor, and the magnetoelectric conversion element in a thickness direction, and a width of the conductor plate.

FIG. 13 is a cross-sectional view of a portion, which corresponds to line A-A in FIG. 1A, of a current sensor 10A according to a modification.

FIG. 14 is a cross-sectional view of a portion, which corresponds to line A-A in FIG. 1A, of a current sensor 10B according to a modification.

FIG. 15 is a cross-sectional view of a portion, which corresponds to line A-A in FIG. 1A, of a current sensor 10C according to a modification.

FIG. 16 is a cross-sectional view of a portion, which corresponds to line A-A in FIG. 1A, of a current sensor 10D according to a modification.

FIG. 17 is a cross-sectional view of a portion, which corresponds to line A-A in FIG. 1A, of a current sensor 10E according to a modification.

FIG. 18 is a cross-sectional view of a portion, which corresponds to line A-A in FIG. 1A, of a current sensor 10F according to a modification.

FIG. 19 is a cross-sectional view of a portion, which corresponds to line A-A in FIG. 1A, of a current sensor 10G according to a modification.

FIG. 20 is a cross-sectional view of a portion, which corresponds to line A-A in FIG. 1A, of a current sensor 10H according to a modification.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solution of the invention.

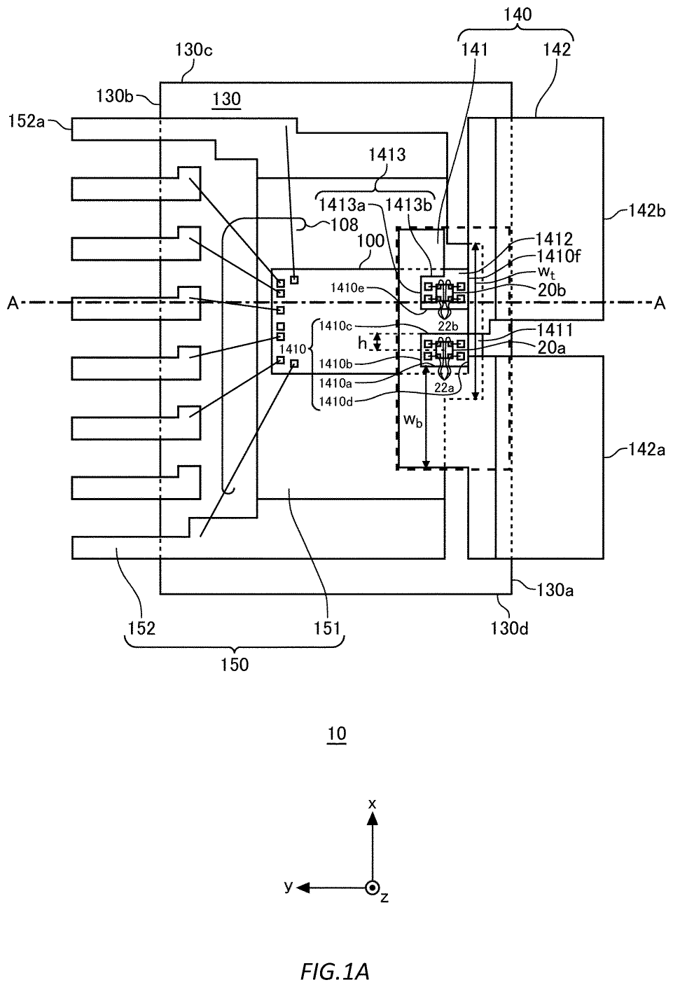

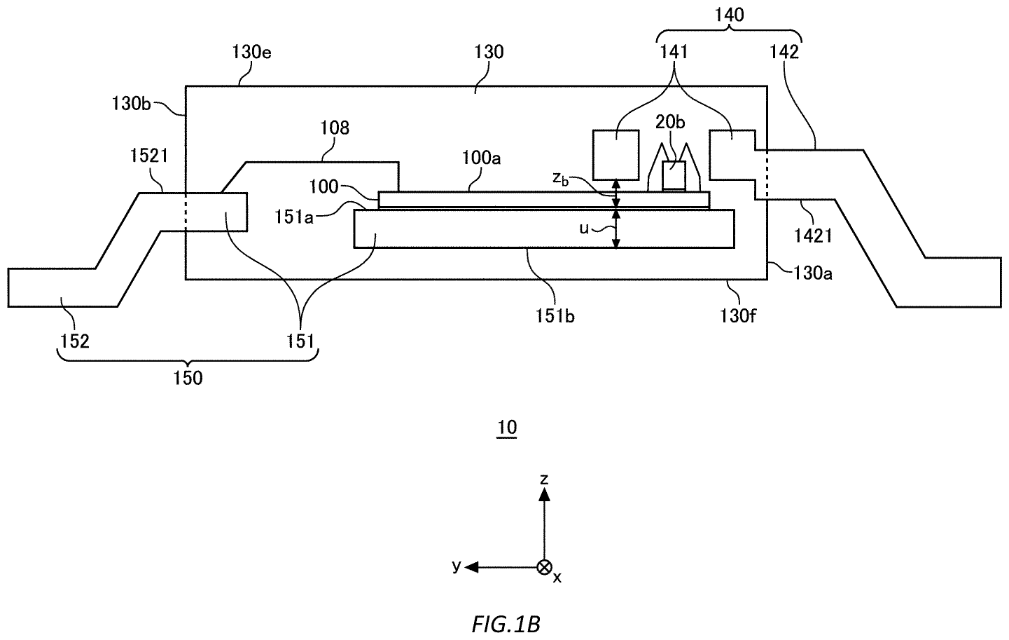

FIGS. 1A and 1B illustrate an internal configuration of a semiconductor package functioning as a current sensor 10 according to the present embodiment. FIG. 1A is a schematic plan view of the current sensor 10 according to the present embodiment as viewed from a ceiling surface side (Z axis direction). FIG. 1B is a cross-sectional view taken along line A-A of the current sensor 10 illustrated in FIG. 1A.

Coordinates are defined in FIG. 1A such that a direction parallel to a plane of paper from bottom to top is an X axis direction, a direction parallel to the plane of the paper from right to left is a Y axis direction, and a direction perpendicular to the plane of the paper from back to front is the Z axis direction. Any one axis of an X axis, a Y axis, and a Z axis is orthogonal to the other axes. The current sensor 10 includes a signal processing IC 100, magnetoelectric conversion elements 20a and 20b, a current conductor 140 through which a measurement current flows, a lead frame 150 on a signal terminal side, and a sealing portion 130.

The current conductor 140 includes a main body portion 141 and a terminal portion 142. The terminal portion 142 includes a pair of terminals 142a and 142b. The main body portion 141 is sealed inside the sealing portion 130 and partially surrounds the magnetoelectric conversion elements 20a and 20b. A first portion 1410 of the main body portion 141 may surround at least three side surfaces of the magnetoelectric conversion element 20a in plan view. The magnetoelectric conversion element 20a may be at least surrounded by side surfaces 1410a, 1410b, and 1410c on an inner side of the first portion 1410. In FIG. 1A, a part of the magnetoelectric conversion element 20a is also surrounded by a side surface 1410d on the inner side of the first portion 1410 in plan view, but the magnetoelectric conversion element 20a may not be surrounded by the side surface 1410d on the inner side of the first portion 1410 in plan view.

A measurement current flows through the terminal portion 142 and the main body portion 141. The pair of terminals 142a and 142b are physically integrated with the main body portion 141 and exposed to an outside of the sealing portion 130. Since the pair of terminals 142a and 142b are physically integrated with the main body portion 141, it is possible to suppress a decrease in reliability due to heat generation of the current conductor 140. In FIG. 1A, the current conductor 140 is a lead frame and is also referred to as a lead frame 140. The lead frame 140 is an example of a first lead frame.

The current conductor 140 does not need to be manufactured in a form of a lead frame in which a plurality of main body portions 141 and a plurality of terminal portions 142 are connected as one metal plate, and may be manufactured using individual metal components.

The lead frame 150 includes a main body portion 151 and a terminal portion 152. The terminal portion 152 includes a plurality of terminals 152a. The main body portion 151 is an example of a conductor plate at least partially overlapping the current conductor 140 in plan view. The main body portion 151 is sealed inside the sealing portion 130, and supports the signal processing IC 100 on a first surface 151a facing the main body portion 141 of the current conductor 140. In the main body portion 151, a surface opposite to the first surface 151a which supports the signal processing IC 100 and faces the main body portion 141 of the current conductor 140 is defined as a second surface 151b of the main body portion 151. Some terminals 152a of the plurality of terminals 152a may be physically integrated with the main body portion 151. At least a part of each of the plurality of terminals 152a is exposed to the outside of the sealing portion 130. The lead frame 150 is an example of a second lead frame. The lead frame 140 and the lead frame 150 may be made of a conductor material containing copper as a main component.

The conductor plate at least partially overlapping the current conductor 140 in plan view may at least partially overlap the main body portion 141 of the current conductor 140 in plan view.

In FIG. 1A, the conductor plate is a part of the main body portion 151 of the lead frame 150, but the conductor plate may be formed as a metal plate separate from the lead frame 150.

The conductor plate may be a non-magnetic body. The conductor plate may be made of a material having an electrical conductivity of 4.6×10⁶ S/m or more. For example, the conductor plate may be made of a material containing copper in an amount of 50% or more. The conductor plate may be made of graphite. The conductor plate may be incorporated in the sealing portion 130 without being exposed from a surface of the sealing portion 130. When the conductor plate is configured separately from the lead frame 150, the conductor plate may be provided on a substrate on which the current sensor 10 is mounted. In this case, the conductor plate may be incorporated in the substrate without being exposed from a surface, on which the current sensor 10 is mounted, of the substrate. Alternatively, the conductor plate may be provided on the substrate on which the current sensor 10 is mounted, and further covered with an insulating material.

The pair of terminals 142a and 142b and the plurality of terminals 152a are arranged to face each other via the signal processing IC 100 in a direction (Y axis direction) intersecting a thickness direction (Z axis direction) of the signal processing IC 100. The direction intersecting the thickness direction may be a direction along a plane (XY plane) orthogonal to the thickness direction. The pair of terminals 142a and 142b are exposed from a side surface 130a of the sealing portion 130. The plurality of terminals 152a are exposed from a side surface 130b of the sealing portion 130 opposite to the side surface 130a.

As illustrated in FIG. 1B, the pair of terminals 142a and 142b and the plurality of terminals 152a may protrude outward from heights, which are different in a thickness direction of the sealing portion 130, of the side surface 130a and the side surface 130b of the sealing portion 130, the side surface 130a and the side surface 130b facing each other. Surfaces 1521 of the plurality of terminals 152a on a same side as a first surface 100a of the signal processing IC 100 may be located at a same height in the thickness direction (Z axis direction) of the sealing portion 130 as that of surfaces 1421 of the pair of terminals 142a and 142b on a same side as a surface of the signal processing IC 100 opposite to the first surface 100a. Alternatively, the surfaces 1521 of the plurality of terminals 152a may be located below the surfaces 1421 of the pair of terminals 142a and 142b in the thickness direction of the sealing portion 130. That is, in a direction from a first surface 130e of the sealing portion 130 on the first surface 100a side of the signal processing IC to a second surface 130f of the sealing portion 130 on the second surface 151b side of the main body portion 151 of the lead frame 150, the surfaces 1521 of the plurality of terminals 152a and the surfaces 1421 of the pair of terminals 142a and 142b may be located at the same height. Alternatively, the surfaces 1521 of the plurality of terminals 152a may be located on the second surface 130f side of the sealing portion 130 with respect to the surfaces 1421 of the pair of terminals 142a and 142b.

The current conductor 140 is electrically insulated from the signal processing IC 100. The current conductor 140 does not have an interface in contact with the signal processing IC 100.

When the current conductor 140 is configured as a lead frame and the lead frame 140 and the lead frame 150 are arranged to overlap each other in the thickness direction, a step may be provided in at least one of the lead frame 140 or the lead frame 150 in the thickness direction in order to ensure insulation between the lead frame 140 and the lead frame 150 or the signal processing IC 100.

Inside the sealing portion 130, the main body portion 141 of the lead frame 140 may be bent and coupled to the terminal portion 142 so as to approach the second surface 130f of the sealing portion 130. The lead frame 140 may be bent and coupled to the terminal portion 142, such that a surface of a portion, which is coupled to the terminal portion 142, in a second surface 141b of the main body portion 141 of the lead frame 140 on the conductor plate 151 side approaches the second surface 130f of the sealing portion 130 by a half or more of a thickness of the current conductor 140 with respect to a surface of a portion, which faces the first surface 100a that is a circuit surface of the signal processing IC 100, in the second surface 141b of the main body portion 141. Inside the sealing portion 130, the main body portion 141 may be curved and coupled to the terminal portion 142 so as to approach the second surface 130f of the sealing portion 130. The main body portion 141 of the lead frame 140 may be curved by bending.

That is, when the main body portion 141 of the lead frame 140 is curved by bending, in the direction from the first surface 130e of the sealing portion 130 to the second surface 130f of the sealing portion 130, in the second surface 141b of the main body portion 141 of the lead frame 140 on the conductor plate 151 side, the portion coupled to the terminal portion 142 may be located on the second surface 130f side of the sealing portion 130 with respect to the surface of the portion facing the first surface 100a that is the circuit surface of the signal processing IC 100, and a difference in height between the surface of the portion facing the first surface 100a that is the circuit surface of the signal processing IC 100 and the portion coupled to the terminal portion 142 may be the half or more of the thickness of the lead frame 140.

Inside the sealing portion 130, the main body portion 151 of the lead frame 150 may be bent and coupled to the terminal portion 152 so as to approach the first surface 130e of the sealing portion 130 that is the first surface 100a side of the signal processing IC. The main body portion 151 of the lead frame 150 may be curved and bent to be coupled to the terminal portion 152 so as to approach the first surface 130e of the sealing portion 130 by a half or more of a thickness of the main body portion 151. The main body portion 151 of the lead frame 150 may be curved by bending.

That is, when the main body portion 151 of the lead frame 150 is curved by bending, in the direction from the first surface 130e of the sealing portion 130 to the second surface 130f of the sealing portion 130, in the second surface 151b of the main body portion 151 of the lead frame 150, the portion coupled to the terminal portion 152 may be located on the first surface 130e side of the sealing portion 130 with respect to the surface of the portion supporting the signal processing IC 100 and functioning as the conductor plate, and a difference in height between the surface of the portion supporting the signal processing IC 100 and functioning as the conductor plate and the portion coupled to the terminal portion 152 may be the half or more of the thickness of the main body portion 151 of the lead frame 150.

Inside the sealing portion 130, the main body portion 141 of the lead frame 140 may be coupled to the terminal portion 142 by a step having a shear surface so as to approach the second surface 130f of the sealing portion 130. The step provided inside the sealing portion 130 of the main body portion 141 of the lead frame 140 for coupling the main body portion 141 of the lead frame 140 to the terminal portion 142 may have a thickness of 0.6 times or less that of the main body portion 141. Further, inside the sealing portion 130, the main body portion 151 of the lead frame 150 may be coupled to the terminal portion 152 by a step having a shear surface so as to approach the first surface 130e of the sealing portion 130. The main body portion 151 of the lead frame 150 may be coupled to the terminal portion 152 by a step having a thickness of 0.6 times or less that of the main body portion 151.

The pair of terminals 142a and 142b protrude from the side surface 130a to a negative side in the Y axis direction, and is further bent to the negative side in the Z axis direction. The plurality of terminals 152a protrude from the side surface 130b toward a positive side in the Y axis direction, and are further bent to the negative side in the Z axis direction. The pair of terminals 142a and 142b may protrude from the side surface 130a to the negative side in the Y axis direction and may be further bent to a positive side in the Z axis direction. The plurality of terminals 152a may protrude from the side surface 130b toward the positive side in the Y axis direction and may be further bent to the positive side in the Z axis direction. The pair of terminals 142a and 142b and the plurality of terminals 152a may not be bent. That is, the pair of terminals 142a and 142b may protrude from the side surface 130a to the negative side in the Y axis direction and may not be bent to the positive side and the negative side in the Z axis direction. The plurality of terminals 152a may protrude from the side surface 130b toward the positive side in the Y axis direction and may not be further bent toward the positive side and the negative side in the Z axis direction.

The signal processing IC 100 may be fixed on the surface 151a of the portion, which supports the signal processing IC 100, of the main body portion 151 of the lead frame 150 via an adhesive layer. The adhesive layer may be a die attach film.

The current conductor 140 has a slit portion 1411. In addition, the current conductor 140 may have a slit portion 1412. The two slit portions 1411 and 1412 are provided in the main body portion 141 and provided inside the sealing portion 130. The magnetoelectric conversion element 20a is partially surrounded by the current conductor 140 by being arranged inside the slit portion 1411 in plan view. In addition, when the current conductor 140 has the slit portion 1412, the magnetoelectric conversion element 20b is partially surrounded by the current conductor 140 by being arranged in the slit portion 1412 in plan view.

That is, the current conductor 140 has the slit portion 1411 to form a first portion surrounding a portion of the magnetoelectric conversion element. Since the current conductor 140 has the slit portion 1412, a protrusion portion 1413 surrounding at least three side surfaces of the magnetic field conversion element 20b in plan view is formed. In addition, since the slit portion 1411 and the slit portion 1412 are provided in the main body portion 141, the main body portion 141, the first portion 1410, and the magnetoelectric conversion elements 20a and 20b are included inside the sealing portion.

In such a case, both the main body portion 141 of the current conductor 140 and the magnetoelectric conversion element 20b are included in the sealing portion 130, and a relative position thereof is hardly changed. Even if a relative position in an XY plane direction between the current conductor 140 or the magnetoelectric conversion element 20b and the conductor plate at a position at least partially overlapping the current conductor 140 is shifted in plan view, an eddy current generated in the conductor plate is generated at a position corresponding to the current conductor 140 regardless of the position of the conductor plate. Therefore, as compared with a case where the current conductor 140 and the magnetoelectric conversion elements 20a and 20b are present outside the sealing portion 130, and the relative position between the current conductor 140 and the magnetoelectric conversion element 20b is likely to change due to mounting misalignment, a form in which the main body portion 141 of the current conductor 140 and the magnetoelectric conversion elements 20a and 20b are included in the sealing portion 130 can suppress a variation in sensitivity suppression due to the eddy current.

By arranging the magnetoelectric conversion element 20a inside the slit portion 1411, three side surfaces of the magnetoelectric conversion element 20a may be surrounded by the current conductor 140. That is, the magnetoelectric conversion element 20a is surrounded by at least the surfaces 1410a, 1410b, and 1410c of the current conductor 140. The magnetoelectric conversion element 20a may or may not be further surrounded by the surface 1410d.

In this way, a current to be measured does not branch, a current density can increase in a portion of the current conductor 140 close to the magnetoelectric conversion element 20a, and as a result, the sensitivity can be further increased. The magnetoelectric conversion element 20a is an example of at least one magnetoelectric conversion unit.

By arranging the magnetoelectric conversion element 20b in the slit portion 1412, three side surfaces of the magnetoelectric conversion element 20b may be surrounded by the current conductor 140. That is, the magnetoelectric conversion element 20b may be surrounded by at least a surface 1410e and a surface 1410f, which define a part of the slit portion 1412, and a surface 1413a of the protrusion portion 1413 of the current conductor 140. The magnetoelectric conversion element 20b may or may not be further surrounded by the surface 1413b of the protrusion portion.

The conductor plate at the position at least partially overlapping the current conductor 140 may at least partially overlap a magnetic sensing surface of the magnetoelectric conversion element 20a in plan view. The conductor plate at the position at least partially overlapping the current conductor 140 may at least partially overlap a magnetic sensing surface of the magnetoelectric conversion element 20b in plan view. By arranging the magnetoelectric conversion element 20b and taking a difference between a magnitude of a magnetic field measured by the magnetoelectric conversion element 20a and a magnitude of the magnetic field measured by the magnetoelectric conversion element 20b, it is possible to detect the magnetic field by the measurement current without being affected by a substantially uniform disturbance magnetic field.

On the other hand, the current conductor 140 may not have the slit portion 1412, and in that case, the protrusion portion 1413 is not present. When the current conductor 140 does not have the slit portion 1412, two side surfaces of the magnetoelectric conversion element 20b may be surrounded by the surface 1410e and the surface 1410f of the current conductor 140.

Here, when the current conductor 140 has the slit portion 1412 and the magnetoelectric conversion element 20b is arranged in the slit portion 1412, a current flowing through the protrusion portion 1413 is weak as compared with a portion of the current conductor 140 surrounding the magnetoelectric conversion element 20a, so that the magnetoelectric conversion element 20b is hardly affected by a skin effect. Similarly, when two side surfaces of the current conductor 140 are surrounded by the surfaces 1410e and 1410f, the magnetoelectric conversion element 20b is hardly affected by the skin effect. Therefore, if the magnetoelectric conversion element 20a satisfies a configuration of the present invention as an example of at least one magnetoelectric conversion unit, the effect of the present invention can be exhibited.

The magnetoelectric conversion elements 20a and 20b may be fixed to the circuit surface of the signal processing IC 100 by die bonding and electrically connected to the signal processing IC 100 by wire bonding. That is, the magnetoelectric conversion elements 20a and 20b may be electrically connected to the signal processing IC 100 via a plurality of wires 22a and 22b. The plurality of wires 22a and 22b may be electrically connected to the magnetoelectric conversion elements 20a and 20b and the signal processing IC 100 in the slit portions 1411 and 1412. That is, the plurality of wires 22a and 22b may electrically connect the magnetoelectric conversion elements 20a and 20b and the signal processing IC 100 without straddling the current conductor 140. In this way, a magnetic flux linked with the wire can be reduced, an induced electromotive force is less likely to be generated, and it becomes easier to respond quickly.

The magnetoelectric conversion elements 20a and 20b may be electrically connected to the signal processing IC 100 by flip chip bonding. The magnetoelectric conversion elements 20a and 20b output, to the signal processing IC 100, signals to be processed by the signal processing IC 100. The magnetoelectric conversion elements 20a and 20b may be configured separately from the signal processing IC 100. That is, the magnetoelectric conversion elements 20a and 20b may be constituted by chips different from chips constituting the signal processing IC 100. The magnetoelectric conversion elements 20a and 20b may be incorporated in the chips constituting the signal processing IC 100.

The magnetic sensing surfaces of the magnetoelectric conversion elements 20a and 20b may be arranged at positions overlapping the side surface on which the slit portion 1411 is provided, when viewed from a direction (X axis direction or Y axis direction) intersecting a thickness direction (Z axis direction) of the magnetoelectric conversion elements 20a and 20b.

Considering a need to stably mount the magnetoelectric conversion elements 20a and 20b and strengthen wire bonding, a thickness of each of the magnetoelectric conversion elements 20a and 20b is preferably twice or less a length of one side of the magnetic sensing surface. Alternatively, the thickness is more preferably equal to or less than a same thickness as that of one side of the magnetic sensing surface. As described above, even when the magnetoelectric conversion elements 20a and 20b are not thickened in order to stably arrange the magnetoelectric conversion elements 20a and 20b, mounting the magnetoelectric conversion elements 20a and 20b on the signal processing IC 100 allows for appropriate adjustment of a distance zb, which is a shorter one of a distance between the conductor plate 151 and the current conductor 140 and a distance between the conductor plate 151 and the magnetic sensing surfaces of the magnetoelectric conversion elements 20a and 20b in the z axis direction, described later. Similarly, incorporating the magnetoelectric conversion elements 20a and 20b in the signal processing IC 100 also facilitates the adjustment.

The signal processing IC 100 is electrically connected to the plurality of terminals 152a via a wire 108. A wire 22 and the wire 108 may be formed of a conductor material containing Au, Ag, Cu, or Al as main components.

The magnetoelectric conversion elements 20a and 20b may protrude from the first surface 100a of the signal processing IC 100 such that the magnetic sensing surfaces of the magnetoelectric conversion elements 20a and 20b overlap the main body portion 141 of the current conductor 140 in side view. Accordingly, a sensitivity of each of the magnetoelectric conversion elements 20a and 20b can be increased.

The magnetoelectric conversion elements 20a and 20b detect the magnetic field in a specific direction that changes according to the measurement current flowing through the current conductor 140, and the signal processing IC 100 amplifies signals corresponding to the magnitudes of the magnetic field and outputs the amplified signals via the terminal 152a. The magnetoelectric conversion elements 20a and 20b are composed of a compound semiconductor formed on a GaAs substrate, and may be chips cut out in a square or rectangular shape in plan view from the Z axis direction.

The magnetoelectric conversion elements 20a and 20b may each have a substrate made of silicon or a compound semiconductor, and a magnetoelectric conversion unit provided on the substrate. The substrate is adjusted in thickness by polishing its surface on the negative side in the Z axis direction. Since the magnetic field in the Z axis direction is detected, for example, a Hall element that detects a longitudinal magnetic field of the current conductor 140 in the thickness direction is suitable as the magnetoelectric conversion elements 20a and 20b. That is, the magnetoelectric conversion elements 20a and 20b may each have the magnetoelectric conversion unit of a longitudinal magnetic field detection type. In addition, if the magnetoelectric conversion elements 20a and 20b are arranged at positions where the magnetic field in any one axis direction on the XY plane is detected, for example, if the magnetoelectric conversion elements 20a and 20b are arranged at positions where the magnetic field in the X axis direction is detected, a magnetoresistive element, a flux gate element, or a vertical Hall element is suitable as the magnetoelectric conversion elements 20a and 20b. More specifically, the magnetoelectric conversion elements 20a and 20b may be arranged so as to overlap the main body portion 141 of the current conductor 140 in plan view from the Z axis direction.

The signal processing IC 100 is a large-scale integrated circuit (LSI). The signal processing IC 100 is a monolithic IC. More specifically, the signal processing IC 100 is a signal processing circuit composed of a Si monolithic semiconductor formed on a Si substrate. The signal processing IC 100 has the circuit surface on which the magnetoelectric conversion elements 20a and 20b are arranged. In the present embodiment, the circuit surface is a first surface 100a corresponding to a ceiling surface of the semiconductor package constituting the signal processing IC 100. The first surface 100a is an example of the circuit surface of the signal processing IC 100. The signal processing circuit processes the output signals corresponding to the magnitudes of the magnetic field output from the magnetoelectric conversion elements 20a and 20b. The signal processing circuit corrects the measurement current flowing through the current conductor 140, based on the output signals, and outputs, via the terminal 152a, an output signal indicating an accurate current value. The signal processing circuit reduces a noise component included in the output signal of the magnetoelectric conversion element 20a and the output signal of the magnetoelectric conversion element 20b, based on the difference between the output signal of the magnetoelectric conversion element 20a and the output signal of the magnetoelectric conversion element 20b, amplifies the output signal of the magnetoelectric conversion element 20a and the output signal of the magnetoelectric conversion element 20b in which the noise component is reduced, calculates a current value of the measurement current based on the amplified output signals, and outputs an output signal indicating the current value.

In the present embodiment, an example in which the current sensor 10 includes two magnetoelectric conversion elements 20a and 20b as the magnetoelectric conversion units will be described. However, it is sufficient that the current sensor 10 includes at least one magnetoelectric conversion element. The at least one magnetoelectric conversion element is, for example, the magnetoelectric conversion element 20a.

The sealing portion 130 seals the magnetoelectric conversion elements 20a and 20b, the main body portion 141 of the current conductor 140, the signal processing IC 100, the wire 22, and the wire 108 with mold resin. The mold resin may be made of, for example, an epoxy-based thermosetting resin to which silica is added, and be molded into a semiconductor package by transfer molding. Note that as described later, the sealing portion 130 may or may not seal the conductor plate that at least partially overlaps the current conductor 140 in plan view.

The measurement current flows from the terminal 142a of the current conductor 140 to the terminal 142b through portions of the main body portion 141 in order of proximity to the magnetoelectric conversion element 20a. In a meantime, a direction in which the current flows is bent in a substantially opposite direction, and a current path does not branch. Accordingly, the current flows so as to surround the magnetoelectric conversion element 20a without dispersing the current sensitivity, so that the sensitivity and the effect of suppressing the skin effect can be enhanced as described later. In an example, in the current sensor 10, the measurement current can flow steadily up to 120 A, and the current exceeding 400 A can flow momentarily. However, when a temperature is assumed to be uniform, the current path does not depend on the current value, and thus the current value has little influence on characteristics of the current sensor 10 described later.

In addition, in the present embodiment, an example in which the main body portion 151 of the lead frame 150 is the conductor plate 151 will be described based on FIGS. 1A and 1B. Hereinafter, unless otherwise specified, when simply expressed as the main body portion 141, it refers to a portion, which is included in the sealing portion, of the current conductor 140, based on FIGS. 1A and 1B. In the present embodiment, in the current sensor 10 configured as described above, the skin effect generated in the current conductor 140 is effectively suppressed by the eddy current generated in the conductor plate 151. The conductor plate 151 does not have a hole or a slit, which penetrates the conductor plate 151, at a position overlapping the magnetic sensing surfaces of the magnetoelectric conversion element 20a and the magnetoelectric conversion element 20b in plan view. Accordingly, it is possible to effectively generate the eddy current in the conductor plate 151.

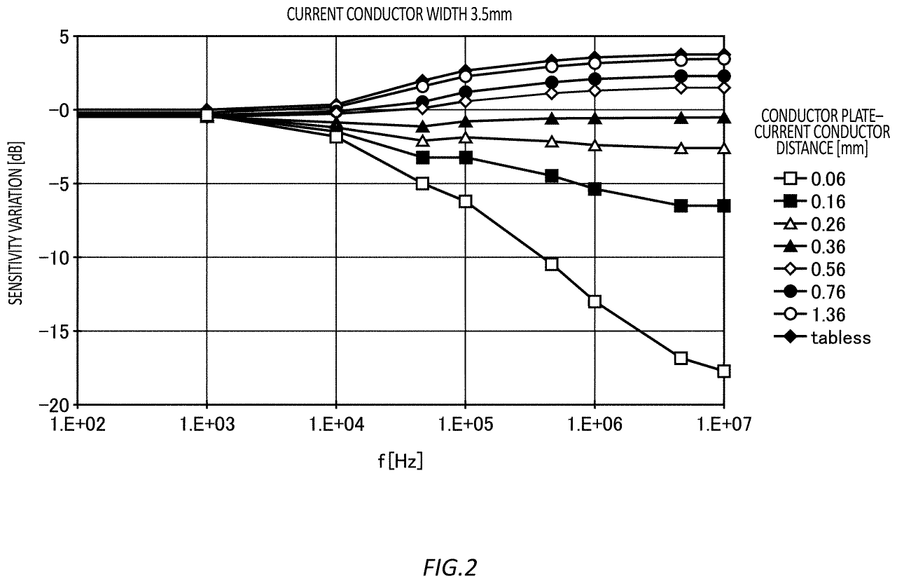

FIG. 2 is a diagram illustrating an example of frequency dependence showing a relationship between a sensitivity variation of the magnetoelectric conversion element 20a and a frequency of the current flowing through the current conductor 140.

FIG. 2 illustrates the frequency dependence of the sensitivity of the magnetoelectric conversion element 20a in a form (tabless form) in which the conductor plate 151 is not arranged at a position facing the main body portion 141, and the frequency dependence of the sensitivity of the magnetoelectric conversion element 20a according to a distance between the main body portion 141 and the conductor plate 151. In this example, the magnetic sensing surface is located at a same height as the second surface 141b of the main body portion 141 in the Z axis direction, and a conductor width w_{b} is 3.5 mm.

In FIG. 2, a line where there is no sensitivity variation even when the frequency of the current is varied, that is, a portion where the value of the sensitivity variation takes a value greater than 0 dB is a portion where the sensitivity of the magnetoelectric conversion element 20a increases due to the influence of the skin effect of the main body portion 141. That is, due to the skin effect, a larger amount of current flows in a vicinity of an edge portion than in a vicinity of a center when viewed in the cross section of the main body portion 141, the current flowing through the main body portion 141 is easily sensed by the magnetoelectric conversion element 20a, and the sensitivity of the magnetoelectric conversion element 20a increases. A portion where the value of the sensitivity variation becomes a value lower than 0 dB is a portion where, due to the influence of the eddy current of the conductor plate 151, the skin effect of the main body portion 141 is suppressed, and the increase in the sensitivity of the magnetoelectric conversion element 20a is suppressed. If the influence of the skin effect of the main body portion 141 can be completely canceled by the eddy current of the conductor plate 151, the sensitivity variation accompanying the frequency variation is 0 dB. However, when the influence of the eddy current of the conductor plate 151 increases, the influence of the eddy current increases as the frequency of the measurement current flowing through the current conductor 140 increases, and thus, when the frequency of the measurement current is high, a decrease in the sensitivity of the electric conversion element 20a increases.

As illustrated in FIG. 2, in the tabless form (a form in which the current sensor 10 does not include the conductor plate 151), the sensitivity of the magnetoelectric conversion element 20a increases as the frequency of the current increases. In a form in which the conductor plate 151 is present, the increase in the sensitivity of the magnetoelectric conversion element 20a can be suppressed by the influence of the eddy current generated in the conductor plate 151. However, as the distance between the conductor plate 151 and the main body portion 141 decreases, the magnetoelectric conversion element 20a is more susceptible to the influence of the eddy current generated in the conductor plate 151. When the distance between the conductor plate 151 and the main body portion 141 is excessively short, for example, 0.06 mm, the sensitivity of the magnetoelectric conversion element 20a is greatly reduced when the frequency of the measurement current flowing through the current conductor 140 is high.

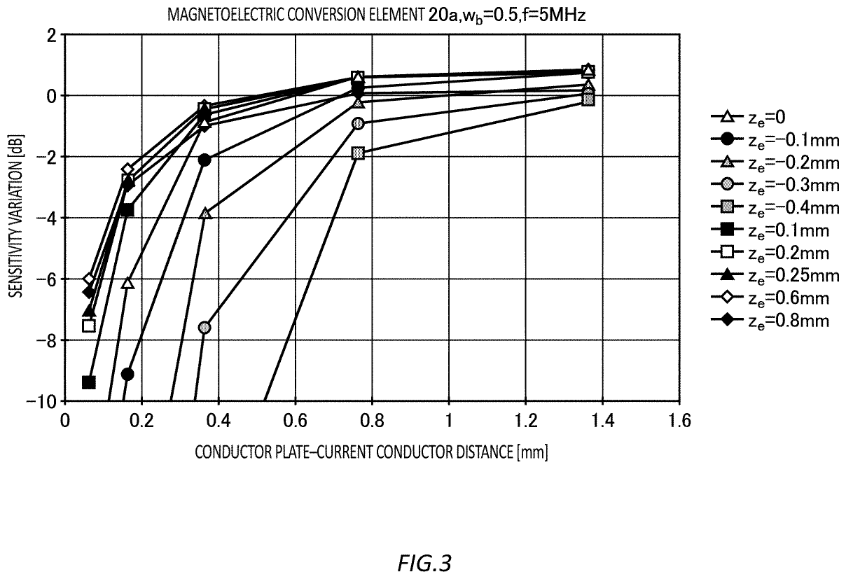

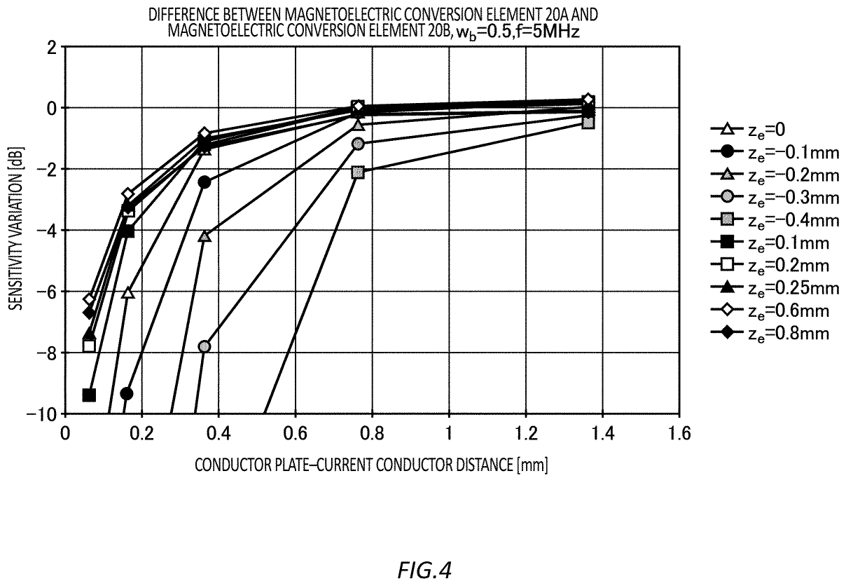

FIG. 3 illustrates an example of a relationship between the sensitivity variation of the magnetoelectric conversion element 20a in which three side surfaces are surrounded by the main body portion 141 in plan view as illustrated in FIG. 1A and the distance between the main body portion 141 and the conductor plate 151. FIG. 4 illustrates an example of a relationship between the sensitivity variation when current sensing is performed based on the difference between the output of the magnetoelectric conversion element 20a and the output of the magnetoelectric conversion element 20b and the distance between the main body portion 141 and the conductor plate 151.

In FIGS. 3 and 4, the conductor width w_{b} is 0.5 mm. In FIGS. 3 and 4, zₑ is a height of a bottom surface of the main body portion 141, that is, a height of the magnetic sensing surface with respect to the second surface 141b of the main body portion 141 in a vicinity of the magnetoelectric conversion element 20a. When the magnetic sensing surface is located at a position higher than that of the second surface 141b of the main body portion 141, that is, in a direction away from the conductor plate 151, zₑ is expressed as a positive value. Conversely, when the magnetic sensing surface is at a position lower than that of the second surface 141b of the main body portion 141, that is, in a direction approaching the conductor plate 151, zₑ is expressed as a negative value.

Comparing FIGS. 3 and 4, it can be seen that characteristics of the sensitivity variation are similar between a case of focusing only on the magnetoelectric conversion element 20a and a case of comprehensively focusing on the magnetoelectric conversion elements 20a and 20b. This is because the cases involve only reversal of a polarity of the magnetic field that affects the magnetoelectric conversion elements 20a and 20b, and there is almost no difference between the sensitivity variation of the magnetoelectric conversion element 20a and the sensitivity variation when the difference between the magnetoelectric conversion elements 20a and 20b is taken. In addition, the magnetoelectric conversion element 20a has three side surfaces surrounded by the main body portion 141, is greatly affected by the magnetic field generated by the current flowing through the current conductor 140, is greatly affected by the skin effect generated in the current conductor 140 and the eddy current generated in the conductor plate 151, and has a sensitivity variation larger than that of the magnetoelectric conversion element 20b. Therefore, the sensitivity variation obtained by taking the difference between the magnetoelectric conversion elements 20a and 20b is a behavior similar to the sensitivity variation of the magnetoelectric conversion element 20a, and is represented by the sensitivity variation when the magnetoelectric conversion element 20a has a plurality of magnetoelectric conversion elements. Hereinafter, a description will be given focusing on the sensitivity variation of the magnetoelectric conversion element 20a.

First, mathematical expression of the sensitivity variation of the magnetoelectric conversion element 20a due to the skin effect will be described.

Outside the conductor, when the magnitude of the magnetic field is denoted by B_{b}, a vacuum magnetic permeability is denoted by μ₀, the current flowing through the conductor is denoted by I_{f}, and a distance from a center of the conductor to a center of the current is denoted by r, the magnetic field B_{b} can be expressed by a following expression according to Ampere's law.

$${B}_{b} = \frac{{μ}_{0} {I}_{f}}{2 π r}$$

Therefore, it can be seen that the magnetic field B_{b} is inversely proportional to the distance r. That is, the magnetic field B_{b} is inversely proportional to the distance from the center of the current to a center of the magnetic sensing surface of the magnetoelectric conversion element 20b.

When a direct current flows through a linear conductor, the distance from the center of the conductor to the center of the magnetic sensing surface of the magnetoelectric conversion element 20a corresponds to the distance r.

As an index of the skin effect occurring in the conductor when a high-frequency current flows through the conductor, there is an index called a skin depth indicating how deep the current flows from the surface of the conductor. The skin depth represents a depth until the magnitude of the current attenuates to 1/e with respect to the conductor surface. When the skin depth is denoted by d, a conductor magnetic permeability is denoted by u, an electrical conductivity is denoted by σ, and the frequency is denoted by f, the skin depth can be expressed by a following expression.

$$d = \sqrt{1 / π f μ \text{?}} \qquad ( 1 )$$

$$\text{?} \text{indicates text missing or illegible when filed}$$

In this regard, the distance r can be derived on the assumption that the current flows from the surface of the conductor to the depth d. In a nonmagnetic material such as copper, it can be assumed that μ=μ₀=4π×10⁻⁷ NA⁻².

However, this assumption assumes that the conductor is linear. In practice, the conductor has a U-shape, so that even when the direct current flows through the conductor, the current concentrates on an inside of the U-shaped portion. That is, the current concentrates on the magnetic sensing surface side of the magnetoelectric conversion element 20a. Therefore, when the magnetic field B_{b} (f=0) is derived with the distance from the center of the conductor to the center of the magnetic sensing surface as r, the magnetic field when the direct current is applied to the conductor becomes smaller than an actual magnetic field, and the sensitivity variation of the magnetoelectric conversion element 20a due to the frequency variation results in a larger calculation result.

In this regard, even for the direct current, it is assumed that the current approaches the magnetic sensing surface side by a certain ratio s from the center of the conductor, and the distance r is expressed by a following expression.

$$r = ( distance from magnetic sensing surface to surface of conductor ) + ( conductor width ) \times ( 1 - s ) / 2 \qquad ( 2 )$$

From Expression 2, for a case where the direct current is applied to the conductor, the distance r from the magnetic sensing surface to the center of the current can be derived, and the magnetic field B_{b} (f=0) applied to the magnetic sensing surface can be derived.

When a state where the direct current is applied to the conductor is changed to a state where an alternating current is applied to the conductor, the current further approaches the magnetic sensing surface side due to the influence of the skin effect.

Here, a magnetic field Bₛₖᵢₙ(f) applied to the magnetic sensing surface during AC application is derived using r=(distance from magnetic sensing surface to surface of conductor)+ (skin depth/2). In this case, in a high frequency region where Bₛₖᵢₙ(f)>B_{b} (f=0), the sensitivity variation due to the skin effect can be derived by using Bₛₖᵢₙ(f)/B_{b} (f=0). On the other hand, the skin effect does not occur in a region, which is other than the high frequency region, where Bₛₖᵢₙ(f)<B_{b}(f=0), so that B_{b}(f)=B_{b} (f=0) is satisfied.

Therefore, when the conductor width is denoted by w_{b}, a shortest distance between the center of the magnetic sensing surface and the surface of the current conductor is denoted by h, the electrical conductivity of the conductor is denoted by σ_{b}, the frequency of the current is denoted by f, and the conductor magnetic permeability at the frequency f is denoted by u, a frequency-induced sensitivity variation due to the skin effect can be expressed by following Expression 3 using a variable s. The variable s is a variable indicating that the current is biased from the conductor center toward the magnetic sensing surface due to the skin effect.

$$\frac{h + \frac{{w}_{b} ( 1 - s )}{2}}{h + \frac{1}{2 \sqrt{π f μ \text{?}}}} \qquad ( 3 )$$

$$\text{?} \text{indicates text missing or illegible when filed}$$

In Expression 3, a denominator represents an amount proportional to the sensitivity of the magnetoelectric conversion element 20a for high-frequency currents, and a numerator represents an amount proportional to the sensitivity of the magnetoelectric conversion element 20a for direct currents.

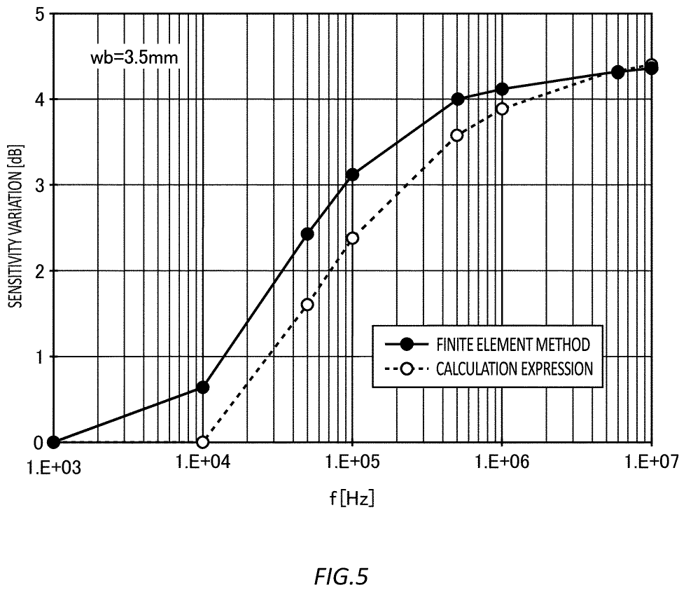

FIG. 5 is a graph illustrating a relationship between the sensitivity variation and the frequency, the relationship being derived by Expression 3. A material of the current conductor is assumed to be copper. One graph illustrates a simulation result obtained by calculating the sensitivity variation using a finite element method with the conductor width w_{b} of 3.5 mm, and another graph illustrates a result obtained by calculating the sensitivity variation using Expression 3 with the conductor width w_{b} of 3.5 mm and s=0.86. As described above, the result of the calculation of the sensitivity variation performed using Expression 3 is not significantly different from the result of the calculation of the sensitivity variation performed using the finite element method. That is, this calculation result suggests that, when the direct current is applied to the conductor, the current is biased by 86% from the center of the conductor to the magnetic sensing surface side, and can effectively explain an actual state of the sensitivity variation at that time.

By partially surrounding at least three sides of the magnetoelectric conversion element 20a, even when the measurement current is a direct current, the current density is concentrated 86% near the magnetoelectric conversion element. That is, s is large. As is clear from Expression 3, when s is large, the influence of the skin effect is small, so that it is easy to improve the frequency characteristics due to the eddy current.

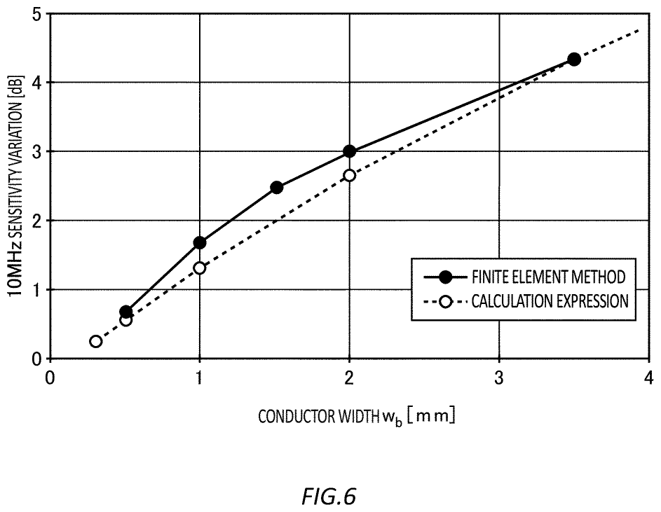

FIG. 6 illustrates an example of a calculation result when a vertical axis represents the sensitivity variation of the magnetoelectric conversion element 20a for the frequency of 10 MHZ and a horizontal axis represents the conductor width w_{b}. One of graphs shows a simulation result obtained by calculating the sensitivity variation using the finite element method, and another graph shows a calculation result when Expression 3 is used with s=0.86. As described above, even when the conductor width is varied, the calculation result using the finite element method and the calculation result using Expression 3 are not significantly different. That is, expressing the frequency-induced sensitivity variation due to the skin effect by Expression 3 can be said to be an effective method.

Next, mathematical expression of the sensitivity variation of the magnetoelectric conversion element 20a due to the eddy current generated in the conductor plate 151 will be described.

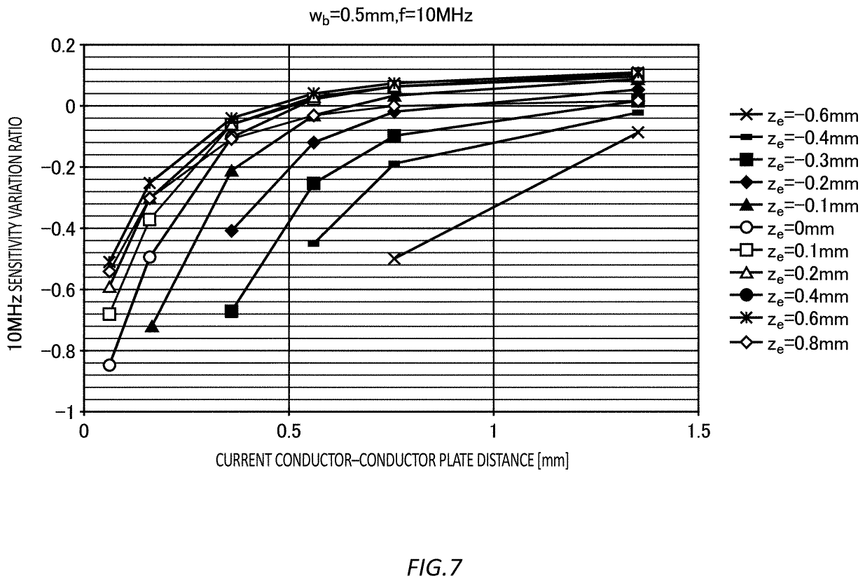

FIG. 7 shows a relationship between the sensitivity variation of the magnetoelectric conversion element 20a and the distance between the main body portion 141 and the conductor plate 151. In FIG. 7, a vertical axis represents the sensitivity variation when the conductor width w_{b} is 0.5 mm and the frequency f is 10 MHz. A horizontal axis indicates the distance between the conductor plate 151 and the main body portion 141. In FIG. 7, zₑ indicates a height to the magnetic sensing surface with respect to the bottom surface of the main body portion 141. That is, FIG. 7 illustrates dependence of the sensitivity variation of the magnetoelectric conversion element 20a on the distance between the main body portion 141 and the conductor plate 151, corresponding to the height zₑ.

As illustrated in FIG. 7, when the distance between the conductor plate 151 and the main body portion 141 is short, when the height zₑ is fixed, the influence of the eddy current generated in the conductor plate 151 tends to increase, and the sensitivity tends to decrease. That is, as the distance between the conductor plate 151 and the main body portion 141 is longer, the influence of the eddy current generated in the conductor plate 151 tends to decrease and the sensitivity tends to increase.

Here, a distance which is a shorter one of the distance between the conductor plate 151 and the main body portion 141 and the distance between the conductor plate 151 and the magnetic sensing surface is denoted by z_{b}.

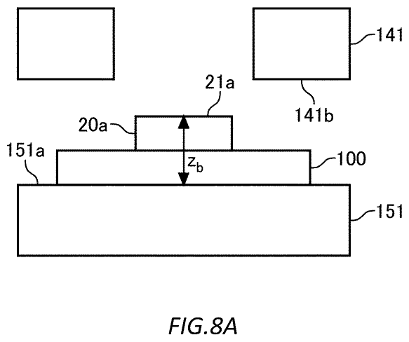

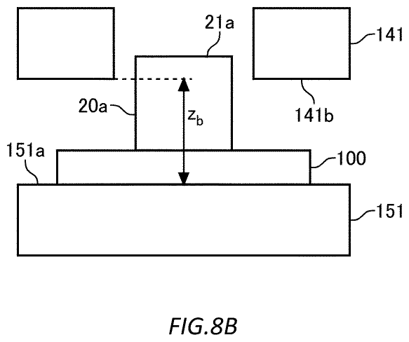

As illustrated in FIG. 8A, when a magnetic sensing surface 21a of the magnetoelectric conversion element 20a is located lower than the surface 141b of the main body portion 141 facing the signal processing IC 100, the distance z_{b} indicates a distance between the surface 151a of the conductor plate 151 on a side where the signal processing IC 100 is arranged and the magnetic sensing surface 21a of the magnetoelectric conversion element 20a. On the other hand, as illustrated in FIG. 8B, when the magnetic sensing surface 21a of the magnetoelectric conversion element 20a is located higher than the surface 141b of the main body portion 141 facing the signal processing IC 100, the distance z_{b} indicates a distance between the surface 151a of the conductor plate 151 on the side where the signal processing IC 100 is arranged and the surface 141b of the main body portion 141 facing the signal processing IC 100.

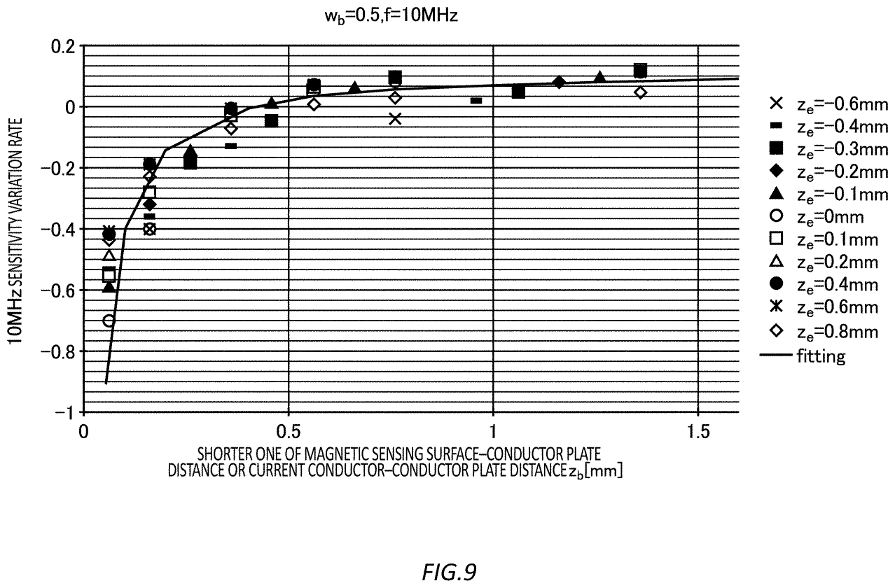

FIG. 9 illustrates a relationship between the sensitivity variation of the magnetoelectric conversion element 20a and the distance z_{b}. In FIG. 9, a vertical axis represents the sensitivity variation when the conductor width w_{b} is 0.5 mm and the frequency f is 10 MHz. A horizontal axis represents the distance z_{b} which is a shorter one of the distance between the conductor plate 151 and the main body portion 141 and the distance between the conductor plate 151 and the magnetic sensing surface. As illustrated in FIG. 9, it can be seen that the sensitivity variation of the magnetoelectric conversion element 20a changes along a single curve with respect to the distance z_{b} even when the height zₑ to the magnetic sensing surface with respect to the bottom surface of the main body portion 141 is changed.

That is, in a region where the current conductor 140 is not present between the magnetic sensing surface 21a and the conductor plate 151, an influence of a change amount ΔB of the magnetic field due to the eddy current depends on the distance between the conductor plate 151 and the magnetic sensing surface 21a. On the other hand, when at least a part of the current conductor 140 is present around a portion between the magnetic sensing surface 21a and the conductor plate 151, a part of the influence of the eddy current is shielded by the current conductor 140, and thus, the influence of the change amount ΔB of the magnetic field due to the eddy current depends on the distance between the conductor plate 151 and the main body portion 141 of the current conductor 140. Therefore, it can be said that it is effective to evaluate the sensitivity variation of the magnetoelectric conversion element 20a due to the eddy current by using the distance z_{b} as a parameter.

In this regard, if the curve as illustrated in FIG. 9 is expressed mathematically, the sensitivity variation of the magnetoelectric conversion element 20a due to the eddy current can be quantitatively evaluated.

Here, when a current is caused to flow through a coil to generate an eddy current in the conductor around the coil, a change amount ΔB_{z} of the magnetic field due to the eddy current can be expressed by following Expression 4 as shown in a document (Y. Li, T. Theodoulidis, G. Y. Tian, Transactions on magnetics, 43, 4010 (2007)).

$$Δ {B}_{z} = \frac{{μ}_{0} {i}_{0}}{2} {\int }_{0}^{∞} {J}_{0} ( ar ) {e}^{- az} \frac{χ ( {ar}_{1} , {ar}_{2} )}{{a}^{2}} ( {e}^{- {az}_{1}} - {e}^{- {az}_{2}} ( R ( a ) da \qquad ( 4 )$$

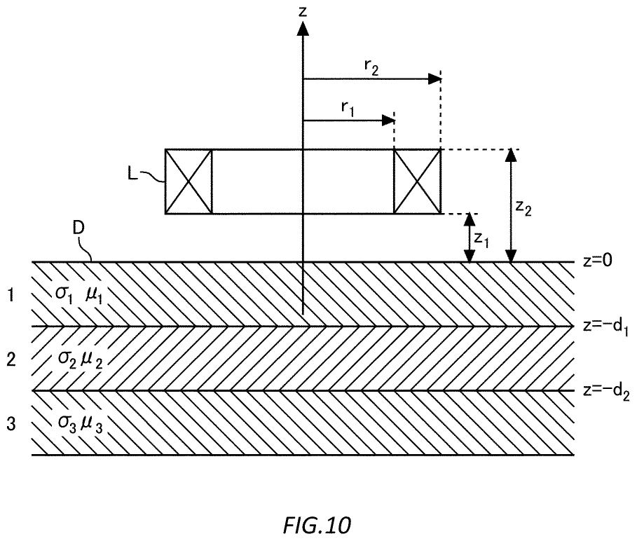

FIG. 10 is a diagram for explaining definitions of parameters of Expression 4 regarding the coil and the conductor (cited from the document “Y. Li, T. Theodoulidis, G. Y. Tian, Transactions on magnetics, 43, 4010 (2007)”). In FIG. 10, a distance from an axial center of a coil L to an inner peripheral surface of the coil L is defined as r₁, and a distance from the axial center of the coil L to an outer peripheral surface of the coil L is defined as r₂. A conductor D is composed of a first layer 1, a second layer 2, and a third layer 3, in order of proximity to the coil L. A distance from a surface of the coil L facing the conductor D to a surface of the first layer 1 facing the coil L is defined as z₁, and a distance from a surface of the coil L opposite to the surface facing the conductor D to the surface of the first layer 1 facing the coil L is defined as z₂. A coordinate of a boundary between the first layer 1 and the second layer 2 is −d₁ with respect to the surface of the first layer 1 facing the coil L, and a coordinate of the boundary between the second layer 2 and the third layer 3 is −d₂ with respect to the surface of the first layer 1 facing the coil L. A magnetic permeability of the first layer 1 is μ₁, and an electrical conductivity thereof is σ₁. A magnetic permeability of the second layer 2 is μ₂, and an electrical conductivity thereof is σ₂. A magnetic permeability of the third layer 3 is μ₃, and an electrical conductivity thereof is σ₃. Further, the current density is defined as i₀. The vacuum magnetic permeability is defined as μ₀. J(x) represents a Bessel function.

In addition, R(a) can be expressed by a following expression when the conductor D is composed of one layer.

$$R ( a ) = \frac{a - {b}_{1}}{a + {b}_{1}}$$

Further, b₁ can be expressed by a following expression.

$${b}_{1} = \frac{\sqrt{{a}^{2} + 2 π jf {μ}_{0} {μ}_{1} {σ}_{1}}}{{μ}_{i}}$$

In addition, X(x₁, x₂) can be expressed by a following expression.

$$χ ( {x}_{1} , {x}_{2} ) = {\int }_{{x}_{2}}^{{x}_{1}} {xJ}_{1} ( x ) dx$$

From above Expression 4, the change amount ΔB_{z} of the magnetic field can be expressed by an integral of a. Then, when z is extracted as a coefficient of a, it can be seen that the change amount ΔB_{z} of the magnetic field is proportional to −1/z. In addition, since the magnitude of the eddy current is proportional to the frequency, the change amount ΔB_{z} of the magnetic field due to the eddy current can be approximated as follows with Ce as a proportional constant.

$$Δ {B}_{z} = - Cef / {z}_{b} \qquad ( 4 )$$

Then, with Ce=4.5×10⁻¹², by adding the term of the skin effect from above Expression 3 to Expression 4, fitting the result, and plotting, a solid line illustrated in FIG. 9 is obtained.

The expression indicated by the change amount ΔB_{z} of the magnetic field due to the eddy current is derived on assumption that an ideal conductor is used. On the other hand, the eddy current generated in an actual conductor, that is, the conductor plate 151 can be reduced by reducing an electrical conductivity of the conductor plate 151, reducing a width of the conductor plate 151, or reducing a thickness of the conductor plate 151. That is, when the influence of the eddy current is large, the eddy current can be suppressed by changing the thickness or electrical conductivity of the conductor plate 151.

The thickness of the conductor plate 151 needs to take into account a penetration depth at which the eddy current can penetrate. That is, the change amount ΔB of the magnetic field due to the eddy current needs to be evaluated by considering whether the thickness of the conductor plate 151 exceeds or does not exceed the penetration depth at which the eddy current can flow, that is, the skin depth. The change amount of the magnetic field due to the eddy current is proportional to a coefficient C_{σt} for correcting the eddy current, which is generated in the conductor plate 151 in a state where both the electrical conductivity and the frequency of the conductor 151 are high, according to conditions such as the electrical conductivity and the frequency.

In this regard, when the skin depth is denoted by d and the thickness of the conductor plate 151 is denoted by u, in a low frequency region, that is, when the thickness of the conductor plate 151 is smaller than the skin depth (u<d), it can be said that the eddy current spreads over the entire conductor plate 151 in the thickness direction, and the eddy current is limited by the thickness of the conductor plate 151. Therefore, since the current path is not limited by the skin depth, a resistance value Rt of the conductor plate 151 can be expressed by a following expression.

$${R}_{t} = {ρ}_{t} * \frac{2 π h}{{uw}_{eff}} = \frac{2 π h}{{uw}_{eff} {σ}_{t}} ∼ \frac{h}{u} {σ}_{t}^{- 1}$$

On the other hand, an electromotive force of the eddy current can be expressed by a following expression using the frequency f of the current flowing through the current conductor 140 with M as a mutual inductance between the current conductor 140 and the conductor plate 151, t as time, and A as a proportional constant.

$${V}_{t} = - M \frac{{dI}_{f}}{dt} , {I}_{f} = Asin 2 π ft$$

Therefore, the electromotive force of the eddy current is proportional to the frequency f of the current flowing through the current conductor 140. Here, Expression 1 representing the skin depth includes the frequency f as a parameter. According to Expression 1, the skin depth decreases as the frequency increases.

From respective expressions of the resistance value Rt and the electromotive force Vt, the change amount ΔB of the magnetic field due to the eddy current is expressed by a following expression.

$$Δ B = \frac{{μ}_{0} {I}_{2}}{2 π h} = \frac{{μ}_{0}}{2 π h} \frac{{V}_{t}}{{R}_{t}} ∼ \frac{u}{{h}^{2}} f {σ}_{t}$$

Therefore, when the thickness of the conductor plate 151 is smaller than the skin depth, that is, u<d, ΔB is proportional to the frequency f and an electrical conductivity σₜ of the conductor plate 151. However, in a region where the frequency f is large, saturation occurs by completely canceling a magnetic field B generated in the main body portion 141, and the dependence on the frequency f is eliminated. That is, in principle, ΔB converges to a certain value, and an upper limit of a change rate of the magnetic field is 1. On the other hand, as for a correction coefficient C_{σt} representing the effect of suppressing the eddy current, in the region where the frequency f is large, the thickness u and σₜ of the conductor plate 151 have no effect in suppressing the magnetic field B generated in the conductor plate 151, and the dependence on the frequency f is eliminated. That is, since the effect of suppressing the eddy current generated in the conductor 151 is eliminated, the correction coefficient converges to 1. Therefore, since both the change rate of the magnetic field due to the eddy current and the correction coefficient C_{σt} converge to 1, the values are the same as a result.

On the other hand, when the thickness of the conductor plate 151 is larger than the skin depth, that is, u>d, the eddy current is limited by the skin depth rather than the conductor plate 151.

When the magnetic permeability of the conductor plate 151 is denoted by μₜ, the electrical conductivity thereof is denoted by σₜ, and the frequency is denoted by f, the skin depth d of the conductor plate 151 can be expressed by a following expression.

$$d = \sqrt{1 / π f {μ}_{t} {σ}_{t}}$$

An effective thickness of the conductor plate 151 in a range in which the eddy current flows can be assumed as d. Therefore, the resistance value Rt of the conductor plate 151 can be expressed by a following expression using a range w_{eff} in which the eddy current of the conductor plate 151 flows.

$${R}_{t} = {ρ}_{t} * \frac{2 π h}{{dw}_{eff}} = \frac{2 π h}{\sqrt{\frac{{σ}_{t}}{π f μ}} {w}_{eff}} ∼ {hf}^{\frac{1}{\text{?}}} {σ}_{t}^{- \frac{1}{\text{?}}} \qquad ( 5 )$$

$$\text{?} \text{indicates text missing or illegible when filed}$$

The change amount ΔB of the magnetic field due to the eddy current can be expressed by a following expression.

$$Δ B = \frac{{μ}_{0} {I}_{2}}{2 π h} = \frac{{μ}_{0}}{2 π h} \frac{{V}_{t}}{{R}_{t}} \sim \frac{1}{{h}^{2}} {f}^{\frac{1}{2}} {σ}_{t}^{\frac{1}{2}}$$

Therefore, when the thickness of the conductor plate 151 is larger than the skin depth (u>d), the change amount ΔB of the magnetic field is proportional to f^{1/2} and σₜ^{1/2}. However, in the region where the frequency f is large, the effect of suppressing the eddy current generated in the conductor 151 is eliminated, so that the correction coefficient converges to 1. That is, in the region where the frequency f is large, the effect of the thickness u and σₜ of the conductor plate 151 in suppressing the magnetic field B generated in the conductor plate 151 is eliminated, and the dependence on the frequency f is eliminated.

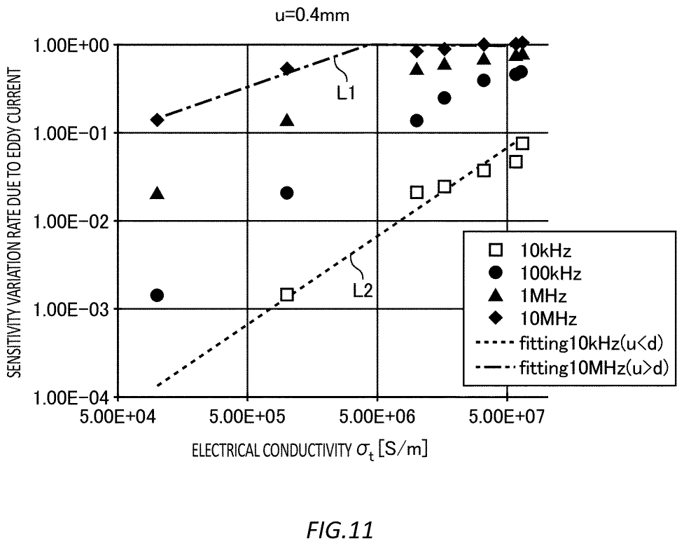

FIG. 11 illustrates a result of obtaining, by using the finite element method, a relationship between the correction coefficient C_{σt} of a sensitivity variation rate due to the eddy current and the electrical conductivity of the conductor plate 151. As described above, for high frequencies, the change amount ΔB of the magnetic field is proportional to a square root of the electrical conductivity σₜ of the conductor plate 151, and thus, the correction coefficient C_{σt} also depends on this. A graph illustrated in FIG. 11 is presented in a double logarithmic graph. Then, for the frequency of 10 MHZ, a slope of a line segment L1 is a power of σₜ^{1/2}, and the graph illustrated in FIG. 11 indicates that, for high frequencies, the correction coefficient C_{σt} of the magnetic field, that is, the effect of suppressing the sensitivity variation rate due to the eddy current is proportional to the square root of the electrical conductivity σₜ of the conductor plate 151.

On the other hand, for low frequencies, the correction coefficient C_{σt} of the sensitivity variation rate is proportional to a first power of the electrical conductivity σₜ of the conductor plate 151. For the frequency of 10 kHz, a slope of a line segment L2 is a power of σₜ, and the graph illustrated in FIG. 11 indicates that, for low frequencies, the correction coefficient C_{σt} of the magnetic field, that is, the effect of suppressing the sensitivity variation rate due to the eddy current is proportional to the first power of the electrical conductivity σₜ of the conductor plate 151.

In consideration of the mathematical expression of the sensitivity variation rate due to the eddy current described above, the thickness u of the conductor plate 151 and the correction term C_{σt} of the electrical conductivity σₜ of the conductor plate 151 can be used to represent how much the sensitivity variation due to the eddy current is suppressed, as divided into following cases.

$$If u > d and {C}_{u > d} \frac{1}{{h}^{2}} \sqrt{f {σ}_{t}} < 1 , \qquad ( 1 )$$

$${C}_{{σ}_{t}} = {C}_{u > d} \frac{1}{{h}^{2}} \sqrt{f {σ}_{t}}$$

$$If u < d and {C}_{u < d} \frac{u}{{h}^{2}} f {σ}_{t} < 1 , \qquad ( 2 )$$

$${C}_{{σ}_{t}} = {C}_{u < d} \frac{u}{{h}^{2}} f {σ}_{t}$$

$$In cases other than ( 1 ) and ( 2 ) , \qquad ( 3 )$$

$${C}_{{σ}_{t}} = 1$$

Here, constants C_{u<d} and C_{u>d} determined to match results of the finite element method are C_{u<d}=4×10⁻¹⁷ and C_{u>d}=1.8×10⁻¹⁴, respectively.

As described above, the conductor plate 151 may be made of a member common to the terminal portion 152. The conductor plate 151 may be a non-magnetic body. For example, the conductor plate 151 may be made of a material containing 50% or more of copper. The conductor plate 151 may be made of a member separate from the terminal portion 152. In this case, the conductor plate 151 may be made of, for example, an aluminum alloy which is easy to process and inexpensive. In addition, the conductor plate 151 may be made of graphite. When the conductor plate 151 is made of graphite, the electrical conductivity can be set to a value of about 1×10⁵, and even when z_{b} is small, the eddy current can be controlled to an appropriate magnitude, and excellent frequency characteristics can be obtained. In addition, when a magnetic body is used as the conductor plate 151, it is also possible to increase the substantial resistivity by considering the magnetic permeability in Expression 5 and suppress the eddy current to an appropriate magnitude. In addition, the conductor plate 151 may be thinned in order to control the eddy current to an appropriate magnitude. In this case, the conductor plate 151 may be formed using a technique such as vapor deposition or plating.

When a width wₜ of the conductor plate 151 decreases, the current path of the eddy current is limited. When it is approximated that the eddy current effectively flows uniformly in a range of w_{eff}/2, the resistance value Rt of the conductor plate 151 at that time can be expressed by a following expression at wₜ<2 w_{eff}. The width wₜ of the conductor plate 151 is a width of a narrowest portion that crosses a portion, which overlaps the magnetoelectric conversion elements 20a and 20b, of the conductor plate 151.

$${R}_{t} = {ρ}_{t} * \frac{2 π h}{{uw}_{t}} = \frac{2 π h}{{uw}_{t} {σ}_{t}} \sim {w}_{t}^{- 1}$$

Therefore, the change amount ΔB of the magnetic field can be expressed by a following expression.

$$Δ B = \frac{{μ}_{0} {I}_{2}}{2 π h} \sim {w}_{t} \qquad ( 6 )$$

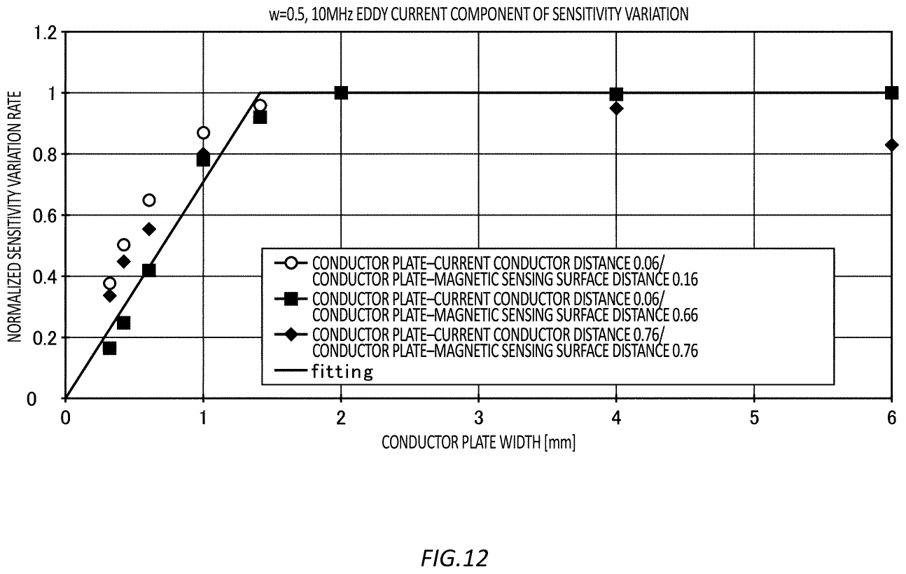

FIG. 12 is a graph showing a relationship between a normalized sensitivity variation rate according to a positional relationship of the conductor plate 151, the main body portion 141 of the current conductor 140, and the magnetoelectric conversion element 20a in the thickness direction, and the width of the conductor plate 151. The normalized sensitivity variation rate is obtained by normalizing with respect to the sensitivity when the width of the conductor plate 151 is sufficiently wide and the eddy current is not limited. As illustrated in FIG. 12, when the width of the conductor plate 151 decreases, the sensitivity variation rate decreases according to Expression 6.

Actually, when w_{eff}=2 h is satisfied with respect to a shortest distance h between the center of the magnetic sensing surface of the magnetoelectric conversion element 20a and the main body portion 141, it can be confirmed that a behavior close to a line segment shown by the finite element method is shown as the graph illustrated in FIG. 12. This reflects that a current to be measured flows with 86% bias toward the magnetic sensing surface in the main body portion 141, and indicates that an eddy current density of the conductor plate 151 is high immediately below the magnetic sensing surface.

Therefore, a correction term C_{w}(wₜ) of the width of the conductor plate 151 can be expressed by a following expression.

$$\begin{matrix}If {w}_{t} < 4 h , \\ {C}_{w} ( {w}_{t} ) = \frac{1}{4 h} {w}_{t} \\ If {w}_{t} \geq 4 h , \\ {C}_{w} ( {w}_{t} ) = 1\end{matrix}$$

The correction term based on the skin effect and the correction term based on the eddy current have been described above.

Incidentally, the sensitivity variation is generally expressed in decibels. In this regard, each of the increase in sensitivity due to the skin effect and the decrease in sensitivity due to the eddy current is expressed in decibels. In this case, a state where an absolute value of the sensitivity variation with the skin effect combined with the eddy current in the presence of the conductor plate 151 is smaller compared to a case where only the sensitivity variation with the skin effect occurs in the conductor plate 141 is a condition where an appropriate effect due to the eddy current can be achieved. This can be expressed by a following expression.

$$\vert 20 {log}_{10} ( \frac{h + 0.07 {w}_{b}}{h + \frac{1}{2 \sqrt{π f {μ}_{b} {σ}_{b}}}} ) + 20 {log}_{10} ( 1 - 4.5 \times {10}^{- 12} \frac{f}{{z}_{b}} {C}_{{σ}_{t}} ( {σ}_{t} ) {C}_{w} ( {w}_{t} ) ) \vert < 20 {log}_{10} ( \frac{h + 0.07 {w}_{b}}{h + \frac{1}{2 \sqrt{π f {μ}_{b} {σ}_{b}}}} )$$

This can be converted to a following expression.

$$- 20 {log}_{10} ( \frac{h + 0.07 {w}_{b}}{h + \frac{1}{2 \sqrt{π f {μ}_{b} {σ}_{b}}}} ) < 20 {log}_{10} ( \frac{h + 0.07 {w}_{b}}{h + \frac{1}{2 \sqrt{π f {μ}_{b} {σ}_{b}}}} ) + 20 {log}_{10} ( 1 - 4.5 \times {10}^{- 12} \frac{f}{{z}_{b}} {C}_{{σ}_{t}} ( {σ}_{t} ) {C}_{w} ( {w}_{t} ) )$$

That is, it can be said that a range in which a magnitude of the decrease in sensitivity by the eddy current does not exceed twice that of the increase in sensitivity due to the skin effect is a range in which the frequency characteristics due to the eddy current can be improved. Therefore, a preferable range in which the eddy current is not excessively large can be expressed by a following expression.

$${( \frac{h + 0.07 {w}_{b}}{h + \frac{1}{2 \sqrt{π f {μ}_{b} {σ}_{b}}}} )}^{- 2} < ( 1 - 4.5 \times {10}^{- 12} \frac{f}{{z}_{b}} {C}_{{σ}_{t}} ( {σ}_{t} ) {C}_{w} ( {w}_{t} ) )$$

Next, a range in which the eddy current is not excessively small and a clear effect beyond manufacturing variations is exhibited will be described.

Among the manufacturing variations, a positional variation in a die bonding process of the magnetoelectric conversion element 20a is considered as a largest factor. The positional variation of a general die bonding device is about +25 μm. From the result of the finite element method, a variation in sensitivity due to this positional variation was 0.23%. The range in which the eddy current exerts beyond this sensitivity can be expressed by a following expression.

$$( 1 - 4.5 \times {10}^{- 12} \frac{f}{{z}_{b}} {C}_{{σ}_{t}} ( {σ}_{t} ) {C}_{w} ( {w}_{t} ) ) < 1 - 0.0023$$

That is, it can be expressed by a following expression.

$$( 1 - 4.5 \times {10}^{- 12} \frac{f}{{z}_{b}} {C}_{{σ}_{t}} ( {σ}_{t} ) {C}_{w} ( {w}_{t} ) ) < 0.9977 \qquad ( 7 )$$

A current sensor following a measured current of 5 MHz is present as a high-speed response current sensor. For a current sensor following a measured current exceeding 5 MHz, it is required to suppress the sensitivity variation due to frequencies of 5 MHz to 10 MHz. That is, the current sensor following a measured current of 10 MHz needs to satisfy a following expression derived by substituting f=10 MHz into above Expression 7.

$${( \frac{h + 0.07 {w}_{b}}{h + \frac{1}{6324 \sqrt{π {μ}_{b} {σ}_{b}}}} )}^{- 2} < ( 1 - 4.5 \times {10}^{- 5} \frac{1}{{z}_{b}} {C}_{{σ}_{t}} ( {σ}_{t} ) {C}_{w} ( {w}_{t} ) ) < 0.9977$$

The current sensor following the measured current of 5 MHz needs to satisfy a following expression derived by substituting f=5 MHz into above Expression 7.

$${( \frac{h + 0.07 {w}_{b}}{h + \frac{1}{4472 \sqrt{π {μ}_{b} {σ}_{b}}}} )}^{- 2} < ( 1 - 2.25 \times {10}^{- 5} \frac{1}{{z}_{b}} {C}_{{σ}_{t}} ( {σ}_{t} ) {C}_{w} ( {w}_{t} ) ) < 0.9977$$

Here, in order to show a specific example, an assumed value is set for each parameter, and then a more simplified expression is numerically derived.

As described above, when the frequency f is 10 MHz, a following expression needs to be satisfied.

$${( \frac{h + 0.07 {w}_{b}}{h + \frac{1}{6324 \sqrt{π} {μ}_{b} {σ}_{b}}} )}^{- 2} < ( 1 - 4.5 \times {10}^{- 5} \frac{1}{{z}_{b}} {C}_{{σ}_{t}} ( {σ}_{t} ) {C}_{w} ( {w}_{t} ) ) < 0.9977 \qquad ( 8 )$$

As another specific example, when the conductor plate 151 is a non-magnetic body, a more simplified expression is numerically derived.

When the conductor plate 151 is a non-magnetic body, it can be approximated that the magnetic permeability of the conductor plate 151 is substantially equal to the vacuum magnetic permeability μ₀=4π×10⁷.

In addition, when the conductor plate 151 is a non-magnetic body, a lower limit of the electrical conductivity σₜ of the conductor plate 151 is preferably 4.6×10⁶ S/m<σₜ, and the thickness u of the conductor plate 151 preferably ranges within 20 μm<u<1 mm.

In particular, when the thicknesses u (m) and σₜ (S/m) of the conductor plate 151 satisfy a relational expression of

$$\begin{matrix}u > d = \sqrt{1 / ( π \times {10}^{7} {μ}_{t} {σ}_{t} )} \\ {C}_{{σ}_{t}} = 1\end{matrix} ,$$

is satisfied, and Expression 8 can be expressed as follows.

$${( \frac{h + 0.07 {w}_{b}}{h + \frac{1}{6324 \sqrt{π {μ}_{b} {σ}_{b}}}} )}^{- 2} < ( 1 - 4.5 \times {10}^{- 5} \frac{1}{{z}_{b}} {C}_{w} ( {w}_{t} ) ) < 0.9977$$

In addition, when the conductor plate 151 is a non-magnetic body, the shortest distance h preferably ranges within 0.05 mm<h<0.5 mm, and the width wₜ of the main body portion 141 preferably ranges within 2 mm<wₜ<20 mm.

Within this range,

C_{w}=1
is satisfied, and Expression 8 can be expressed as follows.

$${( \frac{h + 0.07 {w}_{b}}{h + \frac{1}{6324 \sqrt{{πμ}_{b} {σ}_{b}}}} )}^{- 2} < ( 1 - 4.5 \times {10}^{- 5} \frac{1}{{z}_{b}} ) < 0.9977$$

In addition, when the conductor plate 151 is a non-magnetic body, the maximum conductor width w_{b} of the portion surrounding the magnetoelectric conversion element 20a of the main body portion 141 preferably ranges within 0.4 mm<w_{b}<10 mm, and the distance zb preferably ranges within 0.255 mm<z_{b}<19.6 mm. When each parameter satisfies the above range, Expression 8 is satisfied.

Further, when the current conductor 140 and the conductor plate are made of copper, an assumption of each parameter is set, and then a further simplified expression is numerically derived.

It can be assumed that μ_{b}=μₜ=4π×10⁻⁷ N/A² for the magnetic permeabilities of the current conductor 140 and the conductor plate 151, and σ_{b}=σₜ=5.95×10⁷ S/m for the electrical conductivities of the current conductor 140 and the conductor plate 151. Here, it is assumed that the thickness u and the shortest distance h of the conductor plate 151 and the width wₜ of the current conductor 140 are in a range where the correction term C_{σt} and the correction term C_{wt} are 1. For example, when the range of the thickness u of the conductor plate 151 is 20 μm<u<1 mm, the range of the shortest distance h is 0.05 mm<h<0.5 mm, and the range of the width wₜ of the main body portion 141 is 2 mm<wₜ<20 mm, values of the correction term Cat and the correction term C_{wt} are 1. In this case, the maximum conductor width w_{b} of the portion surrounding the magnetoelectric conversion element 20a of the main body portion 141 is fixed, and a relationship between the distance z_{b}, which is a shorter one of the distance between the conductor plate 151 and the main body portion 141 and the distance between the conductor plate 151 and the magnetic sensing surface, and the shortest distance h between the center of the magnetic sensing surface of the magnetoelectric conversion element 20a and the main body portion 141 is derived. In this case, in the range where the shortest distance h is 0.05 mm<h<0.5 mm, a lower limit of the distance z_{b} can be approximated to be approximately linear with respect to the shortest distance h as a result of numerical calculation. In addition, it can be approximated that the coefficient has an inversely proportional relationship with the maximum conductor width w_{b}. Therefore, the lower limit of the distance z_{b} preferably satisfies a following expression.

$${z}_{b} > \frac{0.3 \times {10}^{- 3}}{{w}_{b}} \times h + 5 \times {10}^{- 5}$$

In addition, the upper limit of the distance z_{b} can be calculated to be 19.6 mm. As described above, an approximate expression of the range of the distance z_{b} when the correction term C_{σt} and the correction term C_{wt} are 1 can be derived.

Here, in Patent Document 1 and Patent Document 4, since an opening is provided in the primary conductor, the current to be measured branches, resulting in a decrease in current density. As a result, the sensitivity cannot be increased. Since the sensitivity in a state where the frequency of the measurement current is low cannot be increased, when the sensitivity variation occurs, the sensitivity variation becomes large in proportion to the sensitivity for direct currents. In addition, since the magnetoelectric conversion element is not partially surrounded, the current density is not concentrated around the magnetoelectric conversion element when the frequency of the measurement current is low. In other words, a relatively uniform current density distribution is obtained. On the other hand, when the frequency is increased, the current path is concentrated on the surface of the current conductor due to the skin effect. Therefore, compared to a case where the measurement current is a direct current, the variation in sensitivity due to the skin effect is considerably large when the frequency is high. Here, in general, the skin effect and the frequency dependence of the magnitude of the eddy current generated in the metal plate are not the same. Therefore, when the skin effect is large, it is difficult to cancel the skin effect with the eddy current in a wide frequency range. In Patent Document 2, when the support member that supports the magnetoelectric conversion element is a semiconductor substrate, the skin effect cannot be suppressed, and when the support member is a metal plate, a distance between the primary conductor and the support portion is short, and the influence of the eddy current is large, so that the sensitivity decreases as the frequency of the measurement current increases. In addition, in Patent Document 2, since the magnetoelectric conversion element is connected to the metal plate only via an adhesive layer, the upper limit of Zb is limited, and the influence of the eddy current easily becomes excessive. In Patent Document 3, since a current rail is arranged on the substrate outside the sealing portion, a relative position between the current to be measured and the sensor element is likely to change due to mounting misalignment, and the variation in sensitivity is large. Further, since the current conductor is linear, the current path is not bent, and the influence of the skin effect is considerably large. Therefore, it is difficult to improve frequency characteristics due to the eddy current in a wide frequency region.

Patent Document 5 discloses an example in which four sides of the magnetoelectric conversion element are surrounded by the current conductor, and the current conductor has a portion close to three side surfaces of the magnetoelectric conversion element and a portion away from one side surface of the magnetoelectric conversion element. However, similarly to the examples disclosed in Patent Document 1 and Patent Document 4, the current density decreases due to branching of the current to be measured. In addition, a resistance value of a portion of the current conductor sandwiched between the magnetoelectric conversion elements is higher than that of the portion away from one side surface of the magnetoelectric conversion element.

Therefore, an amount of current flowing in the portion sandwiched between the magnetoelectric conversion elements decreases, the sensitivity for direct currents decreases, and a ratio of the sensitivity variation is likely to increase.

On the other hand, according to the present embodiment, by designing the current sensor 10 so as to satisfy each of the above conditions, the skin effect generated in the current conductor 140 can be effectively suppressed by the eddy current generated in the conductor plate 151.

In the above description, an example has been described in which the magnetoelectric conversion elements 20a and 20b are longitudinal magnetic field sensing elements. However, even when the magnetoelectric conversion elements 20a and 20b are transverse magnetic field sensing elements such as ferromagnetic magnetoresistive effect elements (MR), tunnel magnetoresistive elements (TMR), or vertical Hall elements, the magnetoelectric conversion elements 20a and 20b can improve the frequency characteristics on a same principle. That is, high-speed response of the current sensor 10 can be realized by canceling the skin effect generated in the main body portion 141 with the eddy current.

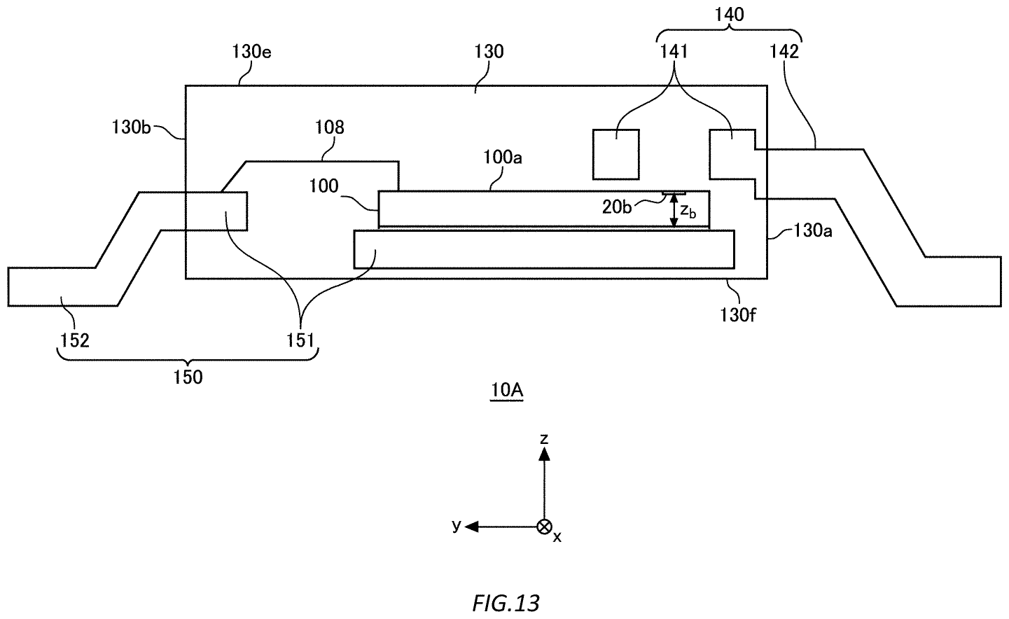

Next, modifications of the current sensor 10 to which the present principle can be applied will be described. Current sensors 10A to 10H described below are different from the current sensor 10 illustrated in FIGS. 1A and 1B in that magnetoelectric conversion elements embedded in the signal processing IC 100 are used as the magnetoelectric conversion elements 20a and 20b. In each modification, the magnetoelectric conversion elements 20a and 20b may be configured separately from the signal processing IC, as illustrated in FIGS. 1A and 1B. In FIGS. 13 to 20, description of equivalent configurations among the members denoted by the reference numerals in FIGS. 1A and 1B is omitted.

The current sensor 10A illustrated in FIG. 13 has same member arrangement relationship as the current sensor 10 except that the magnetoelectric conversion element 20b (20a) is embedded in the signal processing IC 100. Since the magnetoelectric conversion element 20b (20a) is embedded in the signal processing IC 100, the distance from the conductor plate 151 to the magnetic sensing surface of the magnetoelectric conversion element 20b is shorter than the distance from the conductor plate 151 to the main body portion 141. Therefore, the distance z_{b} is a distance from the conductor plate 151 to the magnetic sensing surface of the magnetoelectric conversion element 20b.

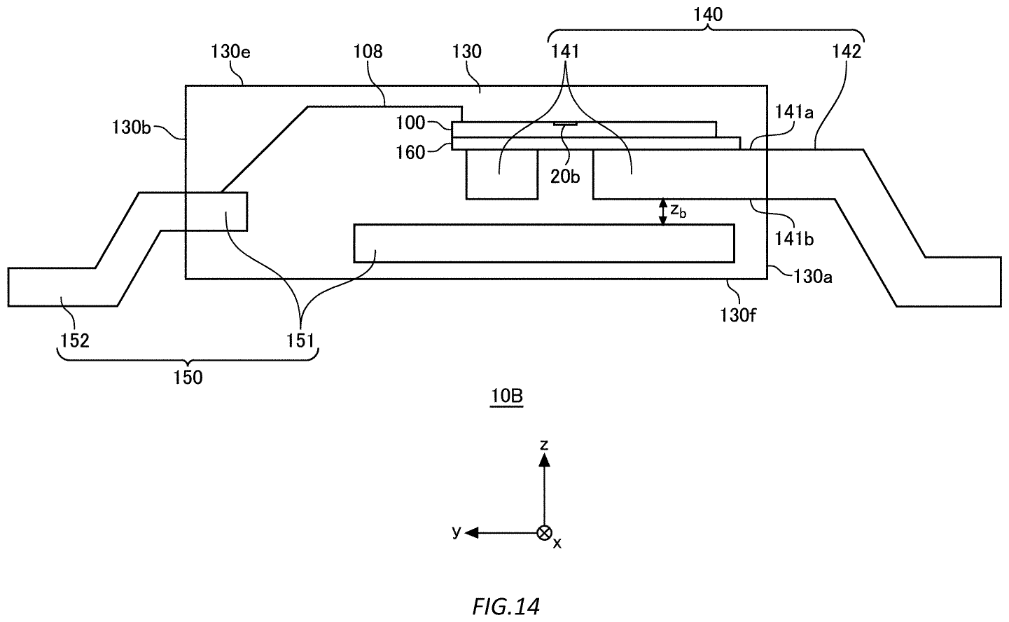

A current sensor 10B illustrated in FIG. 14 is different from the current sensor 10 in that the signal processing IC 100 in which the magnetoelectric conversion element 20b (20a) is embedded is arranged on a surface 141a side opposite to the surface 141b, which faces the conductor plate 151, of the main body portion 141. The signal processing IC 100 is arranged on the surface 141a of the main body portion 141 via an insulating member 160. The insulating member 160 may be a die attach film, an insulating plate, a polymer film, or the like. By arranging the insulating member 160 between the signal processing IC 100 and the main body portion 141, a withstand voltage between the signal processing IC 100 and the main body portion 141 can be ensured. In order to avoid potential creeping discharge, the insulating member 160 may be arranged so as to protrude from the signal processing IC 100 in plan view. Even in such a configuration, the conductor plate 151 may be constituted by the same lead frame 150 as the terminal portion 152.

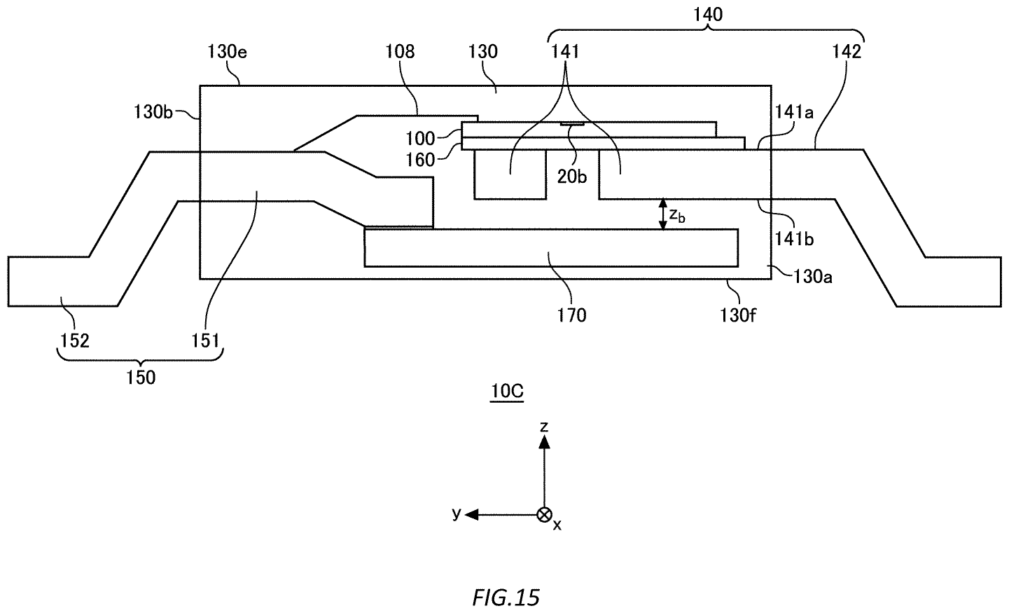

The current sensor 10C illustrated in FIG. 15 is different from the current sensor 10B in that the lead frame 150 on the signal terminal side is bent toward the surface 130f, which is the bottom surface of the sealing portion 130, to have a height different from the height of the main body portion 141 of the current conductor 140 in side view, and then, a conductor plate 170 separate from the lead frame 150 is arranged on a surface of the main body portion 151 of the lead frame 150 on the surface 130f side of the sealing portion 130. The signal processing IC 100 and the magnetoelectric conversion element 20b (20a) are arranged at positions facing the conductor plate 170. In this case, the current conductor 140 and the lead frame 150 do not need to be originally two separate lead frames, and may be separated from a same member. Since the lead frame 140 and the lead frame 150 do not need to overlap each other and be sealed with the sealing portion 130, manufacturing is easy and a manufacturing cost can be reduced. In addition, the conductor plate 170 can be made of a material different from that of the lead frame 150. That is, the conductor plate 170 can be made of a material, such as an aluminum alloy, which is more inexpensive than the lead frame 150, has an optimum electrical conductivity, and has an optimized shape.

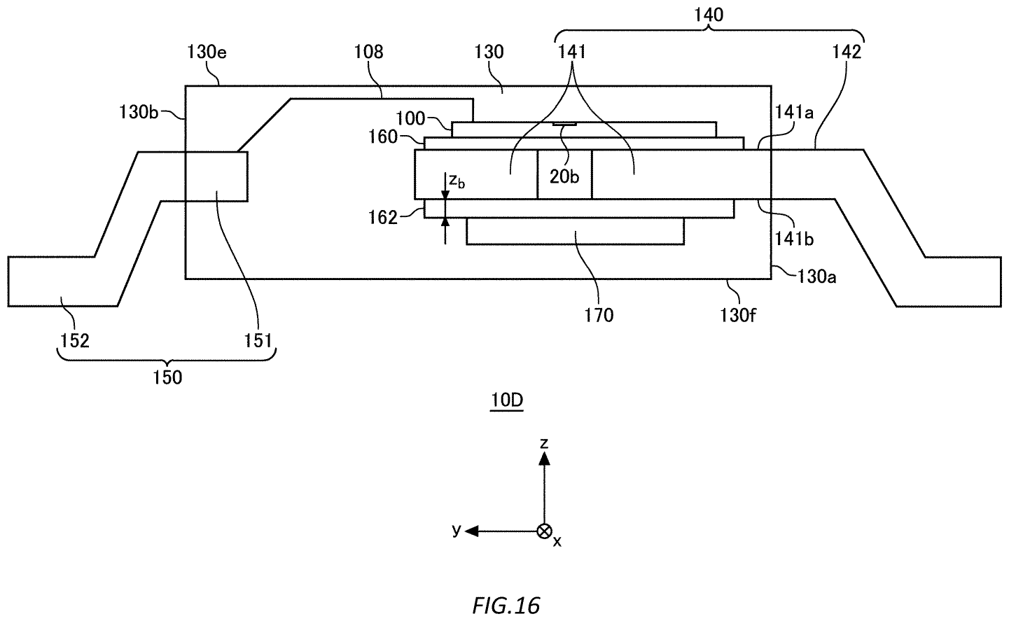

The current sensor 10D illustrated in FIG. 16 is different from the current sensor 10C in that the conductor plate 170 is arranged on the surface 141b of the main body portion 141 of the current conductor 140 via an insulating member 162. Similarly to the current sensor 10C, the conductor plate 170 can be made of a material different from that of the lead frame 150. That is, the conductor plate 170 can be made of a material, such as an aluminum alloy, which is more inexpensive than the lead frame 150, has an optimum electrical conductivity, and has an optimized shape. In addition, since the conductor plate 170 is an individual component, there are no restrictions on a thickness, a width, a material, or the like, and a design for improving frequency characteristics of the current sensor 10D is facilitated.

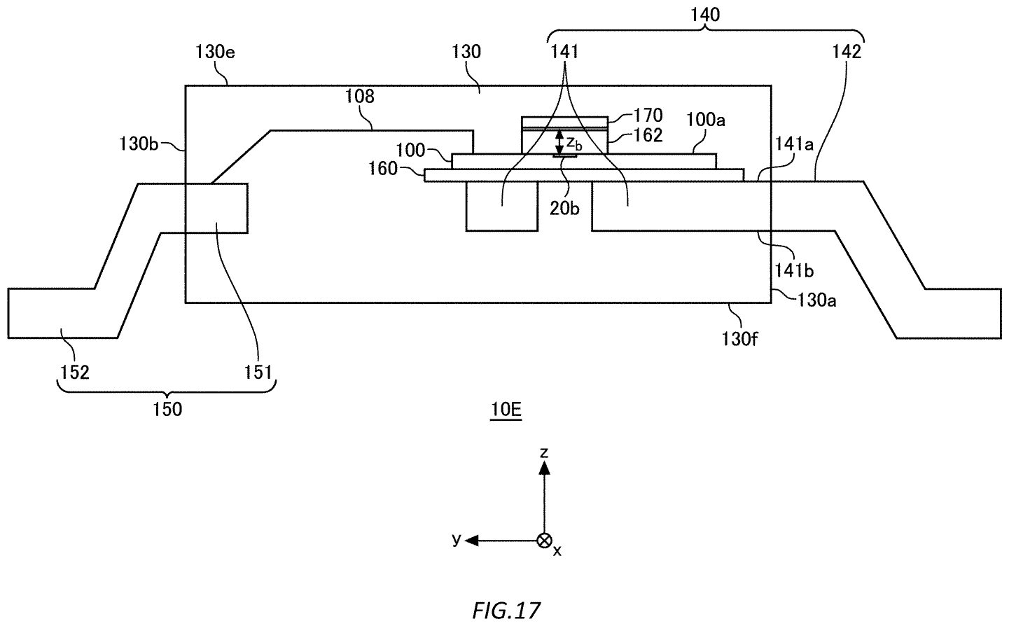

The current sensor 10E illustrated in FIG. 17 is different from the current sensor 10C in that the conductor plate 170 is arranged, via the insulating member 162, at a position facing the magnetic sensing surface of the magnetoelectric conversion element 20b (20a) on the surface 100a that is the circuit surface of the signal processing IC 100. Since the signal processing IC 100 and the conductor plate 170 are mounted on the one surface 141a of the main body portion 141 of the current conductor 140, manufacturing is easy. In addition, a risk of occurrence of discharge between the conductor plate 170 and the current conductor 140 is also small. Further, although a distance between the conductor plate 170 and the magnetic sensing surface is the distance z_{b}, the distance z_{b} can be accurately determined by the insulating member 162 between the conductor plate 170 and the magnetic sensing surface, regardless of a processing accuracy of the lead frame.

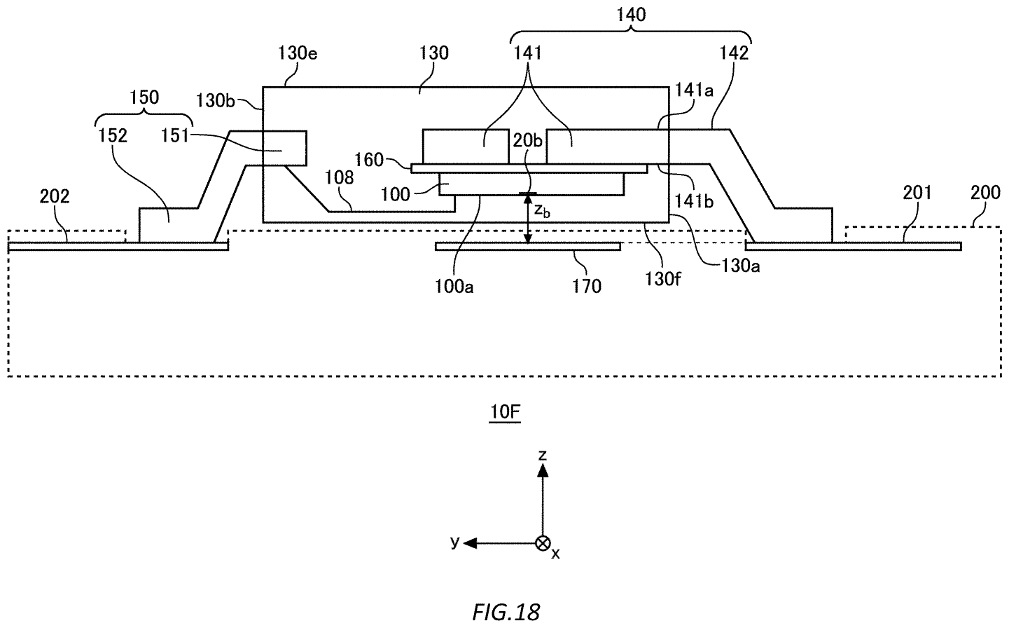

The current sensor 10F illustrated in FIG. 18 is different from the current sensors 10 to 10E in that the conductor plate 170 is not sealed by the sealing portion 130 but is incorporated in a substrate 200 on which the current sensor 10F is mounted. The signal processing IC 100 is arranged on the surface 141b, on the surface 130f side which is the bottom surface of the sealing portion 130, of the main body portion 141 of the current conductor 140 via the insulating member 160. The surface 100a that is the circuit surface of the signal processing IC 100 faces the surface 130f side of the sealing portion 130. That is, the magnetic sensing surface of the magnetoelectric conversion element 20b (20a) incorporated in the signal processing IC 100 faces the surface 130f side of the sealing portion 130. The substrate 200 includes a land portion 201 electrically connected to the terminal portion 142 on the current conductor side and a land portion 202 electrically connected to the terminal portion 152 on the signal terminal side. Further, the substrate 200 incorporates the conductor plate 170 at the position facing the magnetic sensing surface of the magnetoelectric conversion element 20b (20a). In a case of such a configuration, a lead frame for arranging the conductor plate 170 or a dedicated process for arranging the conductor plate 170 is not required, and by appropriately setting a layout of the substrate 200, preparation is possible and simple. The conductor plate 170 may be provided on a surface layer of the substrate 200 instead of being incorporated in the substrate 200. When the conductor plate 170 is located on the surface layer of the substrate 200, the conductor plate 170 may be covered with an insulator such as a resist. Accordingly, it is possible to suppress occurrence of creeping discharge from the terminal portion 142 on the current conductor side to the terminal portion 152 on the signal terminal side. The insulator covering the conductor plate 170 may be a high heat dissipation resin. When the conductor plate 170 is arranged on the surface layer of the substrate 200, the distance z_{b} is a distance from bottom surfaces of the terminal portions 142 and 152 of the current sensor 10F to the magnetic sensing surface. A wiring arranged on the substrate 200 may function as the conductor plate 170. The conductor plate 170 may function as a shield for other wirings. Both the main body portion 141 and the magnetoelectric conversion element 20b are included in the sealing portion 130, and the relative position thereof is hardly changed. Even if a relative position in the XY plane direction between the conductor plate 170 and the current conductor 140 or the magnetoelectric conversion element 20b is shifted, an eddy current generated in the conductor plate 170 is generated at a position corresponding to the current conductor 140 regardless of the position of the conductor plate 170. Therefore, as compared with a case where the entire current conductor 140 and the magnetoelectric conversion elements 20a and 20b are present outside the sealing portion 130, and the relative position between the current conductor 140 and the magnetoelectric conversion element 20b is likely to change due to mounting misalignment, even when the conductor portion 170 is not inside the sealing portion, a form in which the current conductor 140 and the magnetoelectric conversion elements 20a and 20b are included in the sealing portion 130 can suppress a variation in sensitivity suppression due to the eddy current.

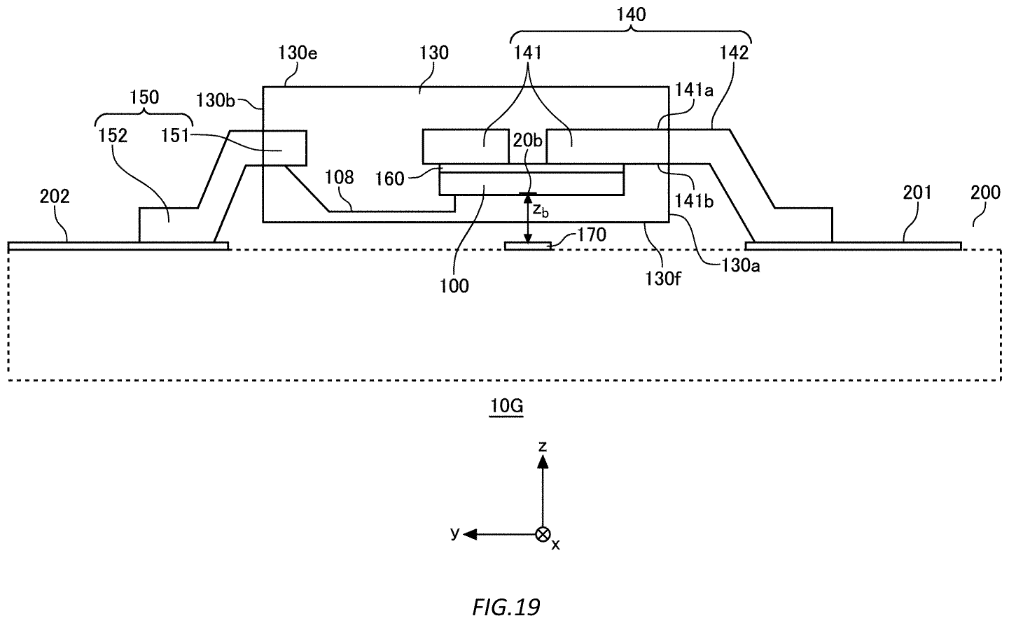

The current sensor 10G illustrated in FIG. 19 is different from the current sensor 10F in which the conductor plate 170 is incorporated in the substrate 200 in that the conductor plate 170 is provided on the surface layer of the substrate 200. A wiring arranged on the substrate 200 may function as the conductor plate 170. Even when the conductor plate 170 is exposed on the surface of the substrate 200, it is unlikely to cause a problem as long as a comparative tracking index (CTI) and a creepage distance of the surface of the substrate 200 (semiconductor package substrate) meet conditions in which the creeping discharge hardly occurs. The conductor plate 170 may function as a shield for other wirings. The distance z_{b} is the distance from the bottom surfaces of the terminal portions 142 and 152 of the current sensor 10F to the magnetic sensing surface.

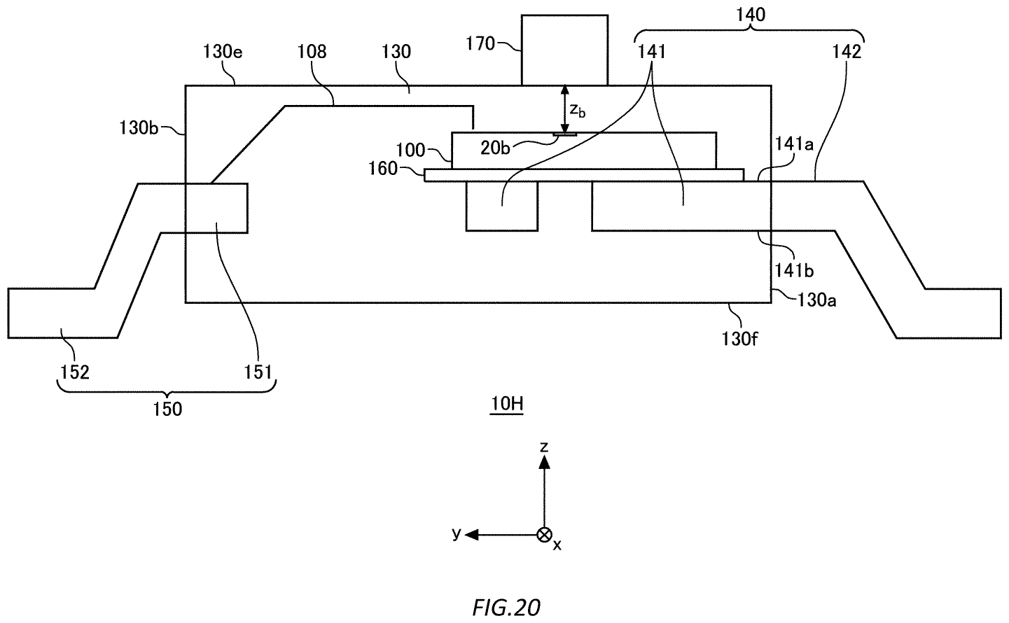

The current sensor 10H illustrated in FIG. 20 is different from the current sensor 10E in which the conductor plate 170 is arranged via the insulating member 162 on the surface 100a that is the circuit surface of the signal processing IC 100, in that the conductor plate 170 is arranged on the surface 130e that is a ceiling surface of the sealing portion 130 in a state of being exposed from the sealing portion 130. The conductor plate 170 may function as a heat sink. The conductor plate 170 may be made of copper or an aluminum alloy. With such a configuration, it is possible to improve frequency characteristics of the current sensor 10H, further, it is possible to promote heat dissipation from the ceiling surface of the sealing portion 130, and it is possible to suppress overheating of the current sensor 10H due to flowing of a large current to the main body portion 141.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### (Item 1)

A current sensor including:
at least one magnetoelectric conversion unit;
a current conductor through which a measurement current measured by the at least one magnetoelectric conversion unit flows;
a signal processing unit which processes a signal output from the at least one magnetoelectric conversion unit;
a conductor plate which at least partially overlaps the current conductor in plan view; and
a sealing portion which seals at least the at least one magnetoelectric conversion unit, the current conductor, and the signal processing unit, in which
the current conductor includes a main body portion which at least partially surrounds one magnetoelectric conversion unit of the at least one magnetoelectric conversion unit in plan view, and the main body portion includes a first portion which surrounds at least three side surfaces of the one magnetoelectric conversion unit, and
when a thickness of the conductor plate is denoted by u (m),
a magnetic permeability of the conductor plate is denoted by μₜ (N/A²),
an electrical conductivity of the conductor plate is denoted by σₜ (S/m),
a magnetic permeability of the current conductor is denoted by μ_{b} (N/A²),
an electrical conductivity of the current conductor is denoted by σ_{b} (S/m),
a shortest distance between a center of a magnetic sensing surface of the at least one magnetoelectric conversion unit and a surface of the current conductor in plan view is denoted by h (m),
a maximum width of the first portion in plan view is denoted by w_{b} (m),
a shorter distance of a distance between the conductor plate and the current conductor and a distance between the conductor plate and the magnetic sensing surface of the at least one magnetoelectric conversion unit in a thickness direction is denoted by z_{b} (m), and
a narrowest width in a portion, which crosses the at least one magnetoelectric conversion unit, of the conductor plate in plan view is denoted by wₜ (m),

$${( \frac{h + 0.07 {w}_{b}}{h + \frac{1}{6324 \sqrt{{πμ}_{b} {σ}_{b}}}} )}^{- 2} < ( 1 - 4.5 \times {10}^{- 5} \frac{1}{{z}_{b}} {C}_{{σ}_{t}} ( {σ}_{t} ) {C}_{w} ( {w}_{t} ) ) < 0.9977$$

is satisfied,
where

$$\begin{matrix}if u > \sqrt{1 / ( π \times {10}^{7} {μ}_{t} {σ}_{t} )} and \\ 4.74 \times {10}^{- 11} \frac{1}{{h}^{2}} \sqrt{{σ}_{t}} < 1 , \\ {C}_{{σ}_{t}} ( {σ}_{t} ) = 4.74 \times {10}^{- 11} \frac{1}{{h}^{2}} \sqrt{{σ}_{t}} , & ( 1 ) \\ if u < \sqrt{1 / ( π \times {10}^{7} {μ}_{t} {σ}_{t} )} and \\ 4 \times {10}^{- 10} \frac{μ}{{h}^{2}} {σ}_{t} < 1 , \\ {C}_{{σ}_{t}} ( {σ}_{t} ) = 4 \times {10}^{- 10} \frac{u}{{h}^{2}} {σ}_{t} , & ( 2 )\end{matrix}$$

(3) in cases other than (1) and (2),

$${C}_{{σ}_{t}} = 1 , \\ if {w}_{t} < 4 h , \\ {C}_{w} ( {w}_{t} ) = \frac{1}{4 h} {w}_{t} , and$$

$$if {w}_{t} \geq 4 h , \\ {C}_{w} ( {w}_{t} ) = 1.$$

### (Item 2)

The current sensor according to item 1, in which the current conductor and the conductor plate are non-magnetic bodies.

### (Item 3)

The current sensor according to item 1, in which the current conductor and the conductor plate are made of a material containing copper in an amount of 50% or more.

### (Item 4)

The current sensor according to item 2, in which
the electrical conductivity σₜ (S/m) of the conductor plate satisfies 4.6×10⁶<σₜ, and
the thickness u (m) of the conductor plate, and
the shortest distance h (m) between the center of the magnetic sensing surface of the at least one magnetoelectric conversion unit and the surface of the current conductor satisfy

$$u > \sqrt{1 / ( π \times {10}^{7} {μ}_{t} {σ}_{t} )} , and$$

$$4.74 \times {10}^{- 11} \frac{1}{{h}^{2}} \sqrt{{σ}_{t}} ≧ 1 , and$$

$${satisfy \\ ( \frac{h + 0.07 {w}_{b}}{h + \frac{1}{6324 \sqrt{{πμ}_{b} {σ}_{b}}}} )}^{- 2} < ( 1 - 4.5 \times {10}^{- 5} \frac{1}{{z}_{b}} {C}_{w} ( {w}_{t} ) ) < 0.9977 , \\ where$$

$$if {w}_{t} < 4 h , \\ {C}_{w} ( {w}_{t} ) = \frac{1}{4 h} {w}_{t} , and$$

$$if {w}_{t} \geq 4 h , \\ {C}_{w} ( {w}_{t} ) = 1.$$

### (Item 5)

The current sensor according to item 4, in which
the shortest distance h (m) between the center of the magnetic sensing surface of the at least one magnetoelectric conversion unit and the surface of the current conductor, and the narrowest width wₜ (m) in the portion, which crosses the at least one magnetoelectric conversion unit, of the conductor plate satisfy

$$5 \times {10}^{- 5} m < h < 5 \times {10}^{- 4} m , and$$

$$2 \times {10}^{- 3} m < {w}_{t} < 2 \times {10}^{- 2} m , and$$

$${satisfy \\ ( \frac{h + 0.07 {w}_{b}}{h + \frac{1}{6324 \sqrt{{πμ}_{b} {σ}_{b}}}} )}^{- 2} < ( 1 - 4.5 \times {10}^{- 5} \frac{1}{{z}_{b}} ) < 0.9977 .$$

### (Item 6)

The current sensor according to item 1, in which the conductor plate is incorporated in the sealing portion without being exposed from a surface of the sealing portion.

### (Item 7)

The current sensor according to item 1, in which the signal processing unit is a signal processing IC that is an IC chip.

### (Item 8)

The current sensor according to item 7, in which the magnetic sensing surface overlaps the signal processing IC in plan view, and an electrical connection portion between the signal processing IC and the at least one magnetoelectric conversion unit does not straddle the current conductor.

### (Item 9)

The current sensor according to item 8, in which
the at least one magnetoelectric conversion unit includes at least one magnetoelectric conversion element separate from the signal processing IC, and
a magnetic sensing surface of the at least one magnetoelectric conversion element protrudes from a circuit surface of the signal processing IC.

### (Item 10)

The current sensor according to item 8, in which a surface of the signal processing IC opposite to a circuit surface is arranged on a surface of the conductor plate facing the current conductor.

### (Item 11)

The current sensor according to item 7, in which
the at least one magnetoelectric conversion unit is incorporated in the signal processing IC, and
a magnetic sensing surface of the at least one magnetoelectric conversion unit does not protrude from a circuit surface of the signal processing IC.

### (Item 12)

The current sensor according to item 7, in which a surface of the signal processing IC opposite to a circuit surface is arranged via an insulating member on a surface opposite to a surface, which faces the conductor plate, of the current conductor.

### (Item 13)

The current sensor according to item 12, in which the conductor plate is arranged via an insulating member on a surface opposite to a surface, on which the signal processing IC is arranged, of the current conductor.

### (Item 14)

The current sensor according to item 7, in which the conductor plate is arranged via an insulating member on a circuit surface of the signal processing IC.

### (Item 15)

The current sensor according to item 7, in which the conductor plate supports the signal processing IC.

### (Item 16)

The current sensor according to item 7, in which the current conductor does not have an interface between the current conductor and a member leading to the signal processing IC.

### (Item 17)

The current sensor according to item 1, in which the at least one magnetoelectric conversion unit is of a longitudinal magnetic field detection type.

### (Item 18)

The current sensor according to item 1, in which the conductor plate does not have a hole or a slit, which penetrates the conductor plate, at a position at least partially overlapping the magnetic sensing surface in plan view.

### (Item 19)

The current sensor according to item 1, further including:
a first terminal portion which is electrically connected to the current conductor and exposed from a first side surface of the sealing portion; and
a second terminal portion which is exposed from a second side surface of the sealing portion facing the first side surface, and outputs a signal output from the signal processing unit.

### (Item 20)

The current sensor according to item 1, in which the current conductor includes a first terminal portion exposed from the sealing portion, and the first portion of the current conductor is integrated with the first terminal portion.

### (Item 21)

The current sensor according to item 19, in which at least a part of the second terminal portion is integrated with the conductor plate.

### (Item 22)

The current sensor according to item 1, in which the conductor plate is not sealed inside the sealing portion, and is electrically insulated from the current conductor and the signal processing unit.

### (Item 23)

A current measurement device including:
a substrate; and
the current sensor which is mounted on the substrate according to item 1, in which
the conductor plate is incorporated in the sealing portion or the substrate without being exposed from a surface of the sealing portion or a surface, on which the current sensor is mounted, of the substrate.

### (Item 24)

A current measurement device including:
a substrate; and
the current sensor which is mounted on the substrate according to item 1, in which
the conductor plate is arranged on the substrate on which the current sensor is mounted.

### (Item 25)

A current measurement device including:
a substrate; and
the current sensor which is mounted on the substrate according to item 7, in which
a surface of the signal processing IC opposite to a circuit surface is arranged on a surface of the current conductor facing the conductor plate, and
the conductor plate is arranged on the substrate on which the current sensor is mounted.

### (Item 26)

The current measurement device according to item 25, in which the conductor plate is incorporated in the substrate. (Item 27)

The current measurement device according to item 25, in which the conductor plate is mounted on a surface layer of the substrate.

### (Item 28)

The current measurement device according to item 27, in which the conductor plate is covered with an insulator.

### (Item 29)

The current measurement device according to item 25, in which the conductor plate is arranged on a surface of the sealing portion on a side of the signal processing IC corresponding to the circuit surface.

### (Item 30)

A current sensor including:
at least one magnetoelectric conversion unit;
a current conductor through which a measurement current measured by the at least one magnetoelectric conversion unit flows;
a signal processing unit which processes a signal output from the at least one magnetoelectric conversion unit;
a conductor plate which at least partially overlaps the current conductor in plan view; and
a sealing portion which seals at least the at least one magnetoelectric conversion unit, the current conductor, and the signal processing unit, in which
the current conductor is a non-magnetic body and includes a main body portion which at least partially surrounds one magnetoelectric conversion unit of the at least one magnetoelectric conversion unit in plan view, and the main body portion includes a first portion which surrounds at least three side surfaces of the one magnetoelectric conversion unit, and
when a thickness of the conductor plate is denoted by u (m),
a shortest distance between a center of a magnetic sensing surface of the at least one magnetoelectric conversion unit and a surface of the current conductor in plan view is denoted by h (m),
a maximum width of the first portion in plan view is denoted by w_{b} (m),
a shorter distance of a distance between the conductor plate and the current conductor and a distance between the conductor plate and the magnetic sensing surface of the at least one magnetoelectric conversion unit in a thickness direction is denoted by z_{b} (m),
a narrowest width in a portion, which crosses the at least one magnetoelectric conversion unit, of the conductor plate in plan view is denoted by wₜ (m), and
an electrical conductivity of the conductor plate is denoted by σₜ (S/m),

$$5 \times {10}^{- 5} m < h < 5 \times {10}^{- 4} m , \\ 4 \times {10}^{- 4} m < {w}_{b} < 1 \times {10}^{- 2} m , \\ 2. 55 \times {10}^{- 4} m < {z}_{b} < 1.96 \times {10}^{- 2} m , \\ 2 \times {10}^{- 3} m < {w}_{t} < 2 \times {10}^{- 2} m , \\ 4.6 \times {10}^{6} S / m < {σ}_{t} , and$$

$$2 \times {10}^{- 5} m < u < 1 \times {10}^{- 3} m$$

are satisfied.

### (Item 31)

A current sensor including:
at least one magnetoelectric conversion unit;
a current conductor through which a measurement current measured by the at least one magnetoelectric conversion unit flows;
a signal processing unit which processes a signal output from the at least one magnetoelectric conversion unit;
a conductor plate which at least partially overlaps the current conductor in plan view; and
a sealing portion which seals at least the at least one magnetoelectric conversion unit, the current conductor, and the signal processing unit, in which
the current conductor is made of a material containing copper in an amount of 50% or more and includes a main body portion which at least partially surrounds one magnetoelectric conversion unit of the at least one magnetoelectric conversion unit in plan view, and the main body portion includes a first portion which surrounds at least three side surfaces of the one magnetoelectric conversion unit, and
when a shortest distance between a center of a magnetic sensing surface of the at least one magnetoelectric conversion unit and the current conductor in plan view is denoted by h,
a maximum width of the first portion in plan view is denoted by w_{b} (m), and
a shorter distance of a distance between the conductor plate and the current conductor and a distance between the conductor plate and the magnetic sensing surface of the at least one magnetoelectric conversion unit in a thickness direction is denoted by z_{b} (m),

$$\frac{0.3 \times {10}^{- 3} [ m ]}{{w}_{b}} \times h + 5 \times {10}^{- 5} [ m ] < {z}_{b} < 1.96 \times {10}^{- 2} [ m ]$$

is satisfied.

### (Item 32)

A current sensor including:
at least one magnetoelectric conversion unit;
a current conductor through which a measurement current measured by the at least one magnetoelectric conversion unit flows;
a signal processing unit which processes a signal output from the at least one magnetoelectric conversion unit;
a conductor plate which at least partially overlaps the current conductor in plan view; and
a sealing portion which seals at least the at least one magnetoelectric conversion unit, the current conductor, and the signal processing unit, in which
the current conductor includes a main body portion which at least partially surrounds one magnetoelectric conversion unit of the at least one magnetoelectric conversion unit in plan view, and the main body portion includes a first portion which surrounds at least three side surfaces of the one magnetoelectric conversion unit, and
when a thickness of the conductor plate is denoted by u (m),
a magnetic permeability of the conductor plate is denoted by μₜ (N/A²),
an electrical conductivity of the current conductor is denoted by σ_{b} (S/m),
a magnetic permeability of the current conductor is denoted by μ_{b} (N/A²),
an electrical conductivity of the conductor plate is denoted by σₜ (S/m),
a shortest distance between a center of a magnetic sensing surface of the at least one magnetoelectric conversion unit and the current conductor in plan view is denoted by h (m),
a maximum width of the first portion in plan view is denoted by w_{b} (m),
a shorter distance of a distance between the conductor plate and the current conductor and a distance between the conductor plate and the magnetic sensing surface of the at least one magnetoelectric conversion unit in a thickness direction is denoted by z_{b} (m), and
a narrowest width in a portion, which crosses the at least one magnetoelectric conversion unit, of the conductor plate in plan view is denoted by wₜ (m),

$$\begin{matrix}{( \frac{h + 0.07 {w}_{b}}{h + \frac{1}{4472 \sqrt{{πμ}_{b} {σ}_{b}}}} )}^{- 2} < ( 1 - 2.25 \times {10}^{- 5} \frac{1}{{z}_{b}} {C}_{{σ}_{t}} ( {σ}_{t} ) {C}_{w} ( {w}_{t} ) ) < 0.9977 \\ is satisfied , \\ where & \\ if u > \sqrt{1 / ( 5 π \times {10}^{6} {μ}_{t} {σ}_{t} )} and 3.35 \times {10}^{- 11} \frac{1}{{h}^{2}} \sqrt{{σ}_{t}} < 1 , \\ {C}_{{σ}_{t}} = 3.35 \times {10}^{- 11} \frac{1}{{h}^{2}} \sqrt{{σ}_{t}} , & ( 1 ) \\ if u < \sqrt{1 / ( 5 π \times {10}^{6} {μ}_{t} {σ}_{t} )} and 2 \times {10}^{- 10} \frac{u}{{h}^{2}} {σ}_{t} < 1 , \\ {C}_{{σ}_{t}} = 2 \times {10}^{- 10} \frac{u}{{h}^{2}} {σ}_{t} , & ( 2 ) \\ in cases other than ( 1 ) and ( 2 ) , \\ {C}_{{σ}_{t}} = 1 , \\ if {w}_{t} < 4 h , \\ {C}_{w} ( {w}_{t} ) = \frac{1}{4 h} {w}_{t} , and \\ if {w}_{t} \geq 4 h , \\ {C}_{w} ( {w}_{t} ) = 1. & ( 3 )\end{matrix}$$

### EXPLANATION OF REFERENCES

10: current sensor;
20a, 20b: magnetoelectric conversion element;
22a, 22b: wire;
100: signal processing IC;
108: wire;
130: sealing portion;
140: current conductor;
141: main body portion;
1411, 1412: slit portion;
142, 152: terminal portion;
150: lead frame;
151, 170: conductor plate;
160, 162: insulating member;
170: conductor plate;
200: substrate; and
201, 202: land portion.

What is claimed is:

1. A current sensor comprising:
at least one magnetoelectric conversion unit;
a current conductor through which a measurement current measured by the at least one magnetoelectric conversion unit flows;
a signal processing unit which processes a signal output from the at least one magnetoelectric conversion unit;
a conductor plate which at least partially overlaps the current conductor in plan view; and
a sealing portion which seals at least the at least one magnetoelectric conversion unit, the current conductor, and the signal processing unit, wherein
the current conductor includes a main body portion which at least partially surrounds one magnetoelectric conversion unit of the at least one magnetoelectric conversion unit in plan view, and the main body portion includes a first portion which surrounds at least three side surfaces of the one magnetoelectric conversion unit, and
when a thickness of the conductor plate is denoted by u (m),
a magnetic permeability of the conductor plate is denoted by μₜ (N/A²),
an electrical conductivity of the conductor plate is denoted by σₜ (S/m),
a magnetic permeability of the current conductor is denoted by μ_{b} (N/A²),
an electrical conductivity of the current conductor is denoted by σ_{b} (S/m),
a shortest distance between a center of a magnetic sensing surface of the at least one magnetoelectric conversion unit and a surface of the current conductor in plan view is denoted by h (m),
a maximum width of the first portion in plan view is denoted by w_{b} (m),
a shorter distance of a distance between the conductor plate and the current conductor and a distance between the conductor plate and the magnetic sensing surface of the at least one magnetoelectric conversion unit in a thickness direction is denoted by z_{b} (m), and
a narrowest width in a portion, which crosses the at least one magnetoelectric conversion unit, of the conductor plate in plan view is denoted by wₜ (m),
$$\begin{matrix}{( \frac{h + 0.07 {w}_{b}}{h + \frac{1}{6324 \sqrt{{πμ}_{b} {σ}_{b}}}} )}^{- 2} < ( 1 - 4.5 \times {10}^{- 5} \frac{1}{{z}_{b}} {C}_{{σ}_{t}} ( {σ}_{t} ) {C}_{w} ( {w}_{t} ) ) < 0.9977 \\ is satisfied , \\ where & \\ if u > \sqrt{1 / ( π \times {10}^{7} {μ}_{t} {σ}_{t} )} and 4.74 \times {10}^{- 11} \frac{1}{{h}^{2}} \sqrt{{σ}_{t}} < 1 , \\ {C}_{{σ}_{t}} ( {σ}_{t} ) = 4.74 \times {10}^{- 11} \frac{1}{{h}^{2}} \sqrt{{σ}_{t}} , & ( 1 ) \\ if u < \sqrt{1 / ( π \times {10}^{7} {μ}_{t} {σ}_{t} )} and 4 \times {10}^{- 10} \frac{u}{{h}^{2}} {σ}_{t} < 1 , \\ {C}_{{σ}_{t}} ( {σ}_{t} ) = 4 \times {10}^{- 10} \frac{u}{{h}^{2}} {σ}_{t} , & ( 2 ) \\ in cases other than ( 1 ) and ( 2 ) , \\ {C}_{{σ}_{t}} = 1 , \\ if {w}_{t} < 4 h , \\ {C}_{w} ( {w}_{t} ) = \frac{1}{4 h} {w}_{t} , and \\ if {w}_{t} \geq 4 h , \\ {C}_{w} ( {w}_{t} ) = 1. & ( 3 )\end{matrix}$$

2. The current sensor according to claim 1, wherein the current conductor and the conductor plate are non-magnetic bodies.

3. The current sensor according to claim 1, wherein the current conductor and the conductor plate are made of a material containing copper in an amount of 50% or more.

4. The current sensor according to claim 2, wherein
the electrical conductivity σₜ (S/m) of the conductor plate satisfies 4.6×10⁶<σₜ, and
the thickness u (m) of the conductor plate, and
the shortest distance h (m) between the center of the magnetic sensing surface of the at least one magnetoelectric conversion unit and the surface of the current conductor satisfy
$$u > \sqrt{1 / ( π \times {10}^{7} {μ}_{t} {σ}_{t} )} , and$$
$$4.74 \times {10}^{- 11} \frac{1}{{h}^{2}} \sqrt{{σ}_{t}} ≧ 1 , and$$
$${satisfy \\ ( \frac{h + 0.07 {w}_{b}}{h + \frac{1}{6324 \sqrt{{πμ}_{b} {σ}_{b}}}} )}^{- 2} < ( 1 - 4.5 \times {10}^{- 5} \frac{1}{{z}_{b}} {C}_{w} ( {w}_{t} ) ) < 0.9977 , \\ where$$
$$if {w}_{t} < 4 h , \\ {C}_{w} ( {w}_{t} ) = \frac{1}{4 h} {w}_{t} , and$$
$$if {w}_{t} \geq 4 h , \\ {C}_{w} ( {w}_{t} ) = 1.$$

5. The current sensor according to claim 4, wherein
the shortest distance h (m) between the center of the magnetic sensing surface of the at least one magnetoelectric conversion unit and the surface of the current conductor, and the narrowest width wₜ (m) in the portion, which crosses the at least one magnetoelectric conversion unit, of the conductor plate satisfy
$$5 \times {10}^{- 5} m < h < 5 \times {10}^{- 4} m , and$$
$$2 \times {10}^{- 3} m < {w}_{t} < 2 \times {10}^{- 2} m , and$$
$${satisfy \\ ( \frac{h + 0.07 {w}_{b}}{h + \frac{1}{6324 \sqrt{{πμ}_{b} {σ}_{b}}}} )}^{- 2} < ( 1 - 4.5 \times {10}^{- 5} \frac{1}{{z}_{b}} ) < 0.9977 .$$

6. The current sensor according to claim 1, wherein the conductor plate is incorporated in the sealing portion without being exposed from a surface of the sealing portion.

7. The current sensor according to claim 1, wherein the signal processing unit is a signal processing IC that is an IC chip.

8. The current sensor according to claim 7, wherein the magnetic sensing surface overlaps the signal processing IC in plan view, and an electrical connection portion between the signal processing IC and the at least one magnetoelectric conversion unit does not straddle the current conductor.

9. The current sensor according to claim 7, wherein
the at least one magnetoelectric conversion unit is incorporated in the signal processing IC, and
a magnetic sensing surface of the at least one magnetoelectric conversion unit does not protrude from a circuit surface of the signal processing IC.

10. The current sensor according to claim 7, wherein a surface of the signal processing IC opposite to a circuit surface is arranged via an insulating member on a surface opposite to a surface, which faces the conductor plate, of the current conductor.

11. The current sensor according to claim 10, wherein the conductor plate is arranged via an insulating member on a surface opposite to a surface, on which the signal processing IC is arranged, of the current conductor.

12. The current sensor according to claim 1, wherein the conductor plate is not sealed inside the sealing portion, and is electrically insulated from the current conductor and the signal processing unit.

13. A current measurement device comprising:
a substrate; and
the current sensor which is mounted on the substrate according to claim 1, wherein
the conductor plate is incorporated in the sealing portion or the substrate without being exposed from a surface of the sealing portion or a surface, on which the current sensor is mounted, of the substrate.

14. A current measurement device comprising:
a substrate; and
the current sensor which is mounted on the substrate according to claim 1, wherein
the conductor plate is arranged on the substrate on which the current sensor is mounted.

15. A current measurement device comprising:
a substrate; and
the current sensor which is mounted on the substrate according to claim 7, wherein
a surface of the signal processing IC opposite to a circuit surface is arranged on a surface of the current conductor facing the conductor plate, and
the conductor plate is arranged on the substrate on which the current sensor is mounted.

16. The current measurement device according to claim 15, wherein the conductor plate is incorporated in the substrate.

17. The current measurement device according to claim 15, wherein the conductor plate is covered with an insulator.

18. The current measurement device according to claim 15, wherein the conductor plate is arranged on a surface of the sealing portion on a side of the signal processing IC corresponding to the circuit surface.

19. A current sensor comprising:
at least one magnetoelectric conversion unit;
a current conductor through which a measurement current measured by the at least one magnetoelectric conversion unit flows;
a signal processing unit which processes a signal output from the at least one magnetoelectric conversion unit;
a conductor plate which at least partially overlaps the current conductor in plan view; and
a sealing portion which seals at least the at least one magnetoelectric conversion unit, the current conductor, and the signal processing unit, wherein
the current conductor is a non-magnetic body and includes a main body portion which at least partially surrounds one magnetoelectric conversion unit of the at least one magnetoelectric conversion unit in plan view, and the main body portion includes a first portion which surrounds at least three side surfaces of the one magnetoelectric conversion unit, and
when a thickness of the conductor plate is denoted by u (m),
a shortest distance between a center of a magnetic sensing surface of the at least one magnetoelectric conversion unit and a surface of the current conductor in plan view is denoted by h (m),
a maximum width of the first portion in plan view is denoted by w_{b} (m),
a shorter distance of a distance between the conductor plate and the current conductor and a distance between the conductor plate and the magnetic sensing surface of the at least one magnetoelectric conversion unit in a thickness direction is denoted by z_{b} (m),
a narrowest width in a portion, which crosses the at least one magnetoelectric conversion unit, of the conductor plate in plan view is denoted by wₜ (m), and
an electrical conductivity of the conductor plate is denoted by σₜ (S/m),
$$5 \times {10}^{- 5} m < h < 5 \times {10}^{- 4} m , \\ 4 \times {10}^{- 4} m < {w}_{b} < 1 \times {10}^{- 2} m , \\ 2. 55 \times {10}^{- 4} m < {z}_{b} < 1.96 \times {10}^{- 2} m , \\ 2 \times {10}^{- 3} m < {w}_{t} < 2 \times {10}^{- 2} m , \\ 4.6 \times {10}^{6} S / m < {σ}_{t} , and$$
$$2 \times {10}^{- 5} m < u < 1 \times {10}^{- 3} m$$
are satisfied.

20. A current sensor comprising:
at least one magnetoelectric conversion unit;
a current conductor through which a measurement current measured by the at least one magnetoelectric conversion unit flows;
a signal processing unit which processes a signal output from the at least one magnetoelectric conversion unit;
a conductor plate which at least partially overlaps the current conductor in plan view; and
a sealing portion which seals at least the at least one magnetoelectric conversion unit, the current conductor, and the signal processing unit, wherein
the current conductor is made of a material containing copper in an amount of 50% or more and includes a main body portion which at least partially surrounds one magnetoelectric conversion unit of the at least one magnetoelectric conversion unit in plan view, and the main body portion includes a first portion which surrounds at least three side surfaces of the one magnetoelectric conversion unit, and
when a shortest distance between a center of a magnetic sensing surface of the at least one magnetoelectric conversion unit and the current conductor in plan view is denoted by h,
a maximum width of the first portion in plan view is denoted by w_{b} (m), and
a shorter distance of a distance between the conductor plate and the current conductor and a distance between the conductor plate and the magnetic sensing surface of the at least one magnetoelectric conversion unit in a thickness direction is denoted by z_{b} (m),
$$\frac{0.3 \times {10}^{- 3} [ m ]}{{w}_{b}} \times h + 5 \times {10}^{- 5} [ m ] < {z}_{b} < 1.96 \times {10}^{- 2} [ m ]$$
is satisfied.
